(19) United States
(12) Patent Application Publication
(10) Pub. No.: US 2016/0083844 A1
(43) Pub. Date: Mar. 24, 2016

(54) Substrate Processing Apparatus, Gas Introduction Shaft and Gas Supply Plate

(71) Applicant: Hitachi Kokusai Electric Inc., Tokyo (JP)

(72) Inventors: Eisuke NISHITANI, Toyama (JP); Kazuyuki TOYODA, Toyama (JP)

(21) Appl. No.: 14/826,782

(22) Filed: Aug. 14, 2015

(30) Foreign Application Priority Data
Sep. 24, 2014 (JP) 2014-193362

(51) Int. Cl. C23C 16/455; C23C 16/44

(52) U.S. Cl. CPC C23C 16/45561; C23C 16/4412; C23C 16/45574

(57) ABSTRACT

Provided is a substrate processing apparatus including: a substrate support unit; a gas supply plate including a plurality of gas distribution pipes connected to a plurality of gas supply regions; and a gas introduction shaft mounted on the gas supply plate. The gas introduction shaft includes a plurality of gas introduction pipes. Each of the plurality of gas introduction pipes is connected to each of the plurality of gas distribution pipes via each of a plurality of gas discharging spaces having an annular shape.

### CROSS REFERENCE TO RELATED APPLICATIONS

This application claims foreign priority under 35 U.S.C. §119(a)-(d) to Application No. JP 2014-193362 filed on Sep. 24, 2014, the entire contents of which are hereby incorporated by reference.

### FIELD OF THE INVENTION

The present invention relates to a substrate processing apparatus, a gas introduction shaft and a gas supply plate that are used in a process of manufacturing a semiconductor device.

### BACKGROUND

In a process of manufacturing a semiconductor device, various process processing is performed on a substrate such as a wafer or the like. In the process processing, for example, there is thin film-forming processing performed by an alternate supply method. The alternate supply method is a method of alternately supplying at least two types of processing gases such as a source gas and a reactive gas that reacts with the source gas to a substrate serving as a processing target, and reacting the gases on a surface of the substrate to form and deposit a layer one by one to form a film having a desired film thickness.

As a type of the substrate processing apparatus for performing the thin film-forming processing by the alternate supply method, the following configuration is provided. That is, the substrate processing apparatus has a circular processing space, when seen in a plan view, which is divided into a plurality of processing regions, and different types of gases are supplied into the processing regions. In addition, as a substrate support unit on which a substrate serving as a processing target is placed is rotated such that the substrate passes through the processing regions in sequence, thin film-forming processing of the substrate is performed.

### SUMMARY

The present invention is directed to provide a substrate processing apparatus, a gas introduction shaft and a gas supply plate that are capable of easily or conveniently providing a variation in sizes of a plurality of processing regions according to process processing when the process processing in which a substrate passes through the processing regions in sequence is performed.

According to an aspect of the present invention, there is provided a substrate processing apparatus including: a substrate support unit where a substrate is placed; a gas supply plate including: a processing space ceiling plate facing the substrate support unit; and a plurality of gas distribution pipes connected to a plurality of gas supply regions disposed between the processing space ceiling plate and the substrate support unit; and a gas introduction shaft mounted on the gas supply plate, the gas introduction shaft including a plurality of gas introduction pipes where different types of gases flow, wherein each of the plurality of gas introduction pipes is connected to each of the plurality of gas distribution pipes via each of a plurality of gas discharging spaces having annular shape, and the plurality of gas discharging spaces have different diameters and are disposed on different planes.

### BRIEF DESCRIPTION OF THE DRAWINGS

FIG. 1 is a view for schematically showing a schematic configuration example of a major part of a substrate processing apparatus according to an embodiment of the present invention;

FIGS. 2A through 2D are views for describing a configuration example of a gas supply plate included in the substrate processing apparatus according to the embodiment of the present invention: FIG. 2A is a conceptual view of each region in a processing space when seen in a plan view, FIG. 2B is a side cross-sectional view taken along line C-C of FIG. 2A, FIG. 2C is a side cross-sectional view taken along line D-D of FIG. 2A, and FIG. 2D is a side cross-sectional view taken along line E-E of FIG. 2A;

FIG. 3 is a perspective view showing another configuration view of the gas supply plate included in the substrate processing apparatus according to the embodiment of the present invention, and a configuration example of a gas introduction shaft included in the substrate processing apparatus;

FIGS. 4A and 4B are views for describing a configuration example of a fitting state of the gas introduction shaft included in the substrate processing apparatus according to the embodiment of the present invention: FIG. 4A is a perspective view of the configuration example, and FIG. 4B is a side cross-sectional view of the configuration example;

FIGS. 5A through 5C are views for describing a configuration example of a gas introduction pipe in the gas introduction shaft included in the substrate processing apparatus according to the embodiment of the present invention: FIG. 5A is a cross-sectional view taken along line F-F of FIG. 3, FIG. 5B is a cross-sectional view taken along line G-G of FIG. 3, and FIG. 5C is a cross-sectional view taken along line H-H of FIG. 3;

FIG. 6 is a view for describing a configuration example of a gas supply groove section in the gas introduction shaft included in the substrate processing apparatus according to the embodiment of the present invention;

FIG. 7 is a conceptual view schematically showing a configuration of a gas introduction shaft and a gas pipe of the substrate processing apparatus according to the embodiment of the present invention;

FIG. 8 is a flowchart showing a substrate processing process according to an embodiment of the present invention;

FIG. 9 is a flowchart showing a relative position movement processing operation performed in the film-forming process of FIG. 8 in detail;

FIG. 10 is a flowchart showing a gas supply exhaust processing operation performed in the film-forming process of FIG. 8 in detail;

FIGS. 11A and 11B are views for describing an example of sizes of areas of gas supply regions of the gas supply plate included in the substrate processing apparatus according to the embodiment of the present invention when seen in a plan view, FIG. 11A is a plan view showing an specific example, and FIG. 11B is a plan view showing another specific example;

FIGS. 12A and 12B are views for describing an example of sizes of areas of gas supply regions in a gas supply plate included in a substrate processing apparatus according to another embodiment of the present invention when seen in a plan view, FIG. 12A is a plan view showing a specific example, and FIG. 12B is a plan view showing another specific example; and

FIG. 13 is a view for describing a configuration example for generating a reactive gas in a plasma state in the substrate processing apparatus of the other example of the present invention.

### DETAILED DESCRIPTION

### Embodiment

Hereinafter, an embodiment of the present invention will be described with reference to the accompanying drawings.

### (1) Configuration of Substrate Processing Apparatus

A substrate processing apparatus according to the embodiment is configured as a sheet-type substrate processing apparatus. The substrate serving as the processing target of the substrate processing apparatus may be, for example, a semiconductor wafer substrate manufactured as a semiconductor device (hereinafter, simply referred to as a “wafer”). While etching, ashing, film-forming processing and so on may be exemplarily performed as the processing performed on the substrate, in particular, the film-forming processing is performed by an alternate supply method in the embodiment.

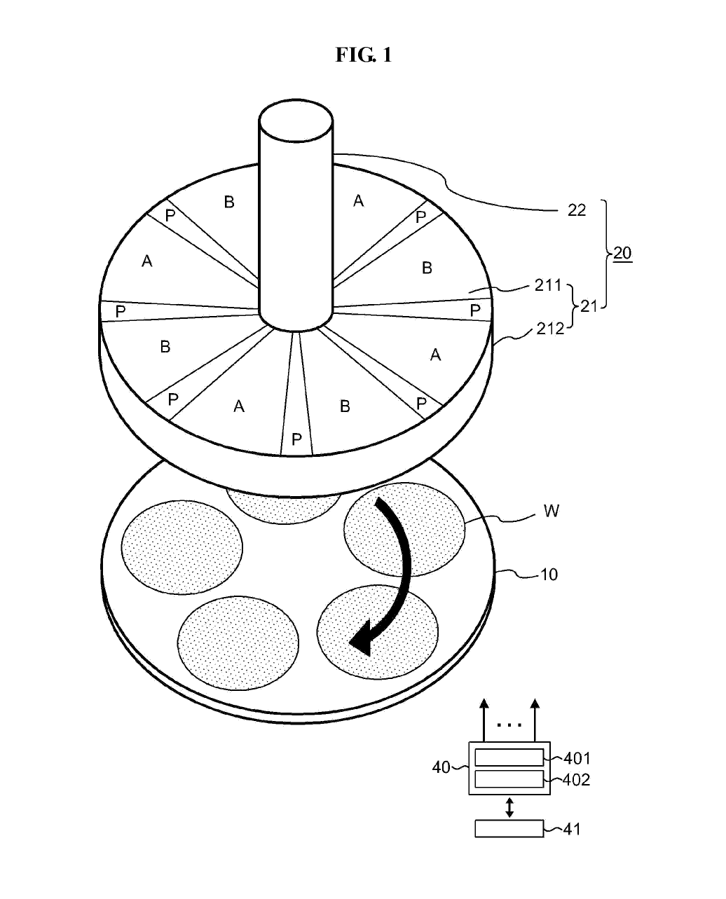

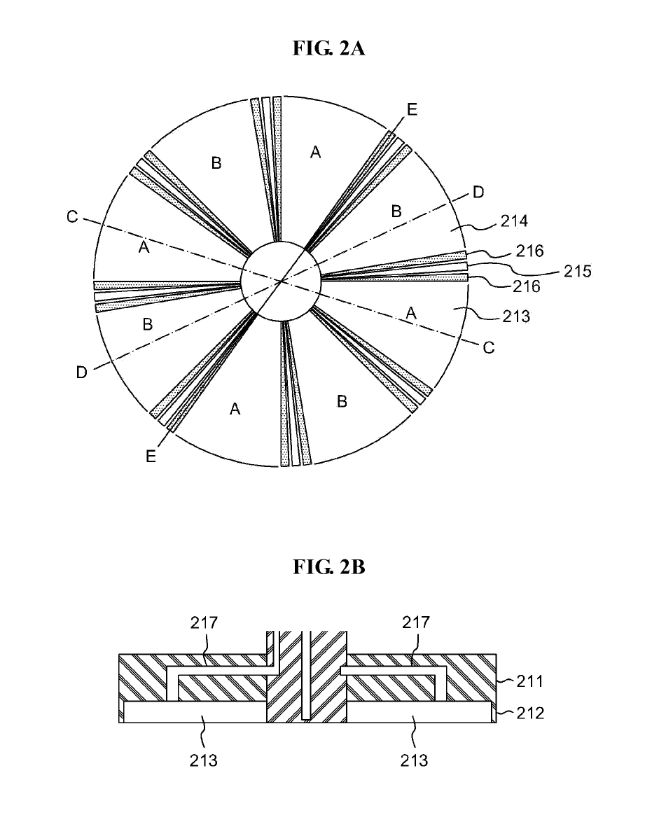

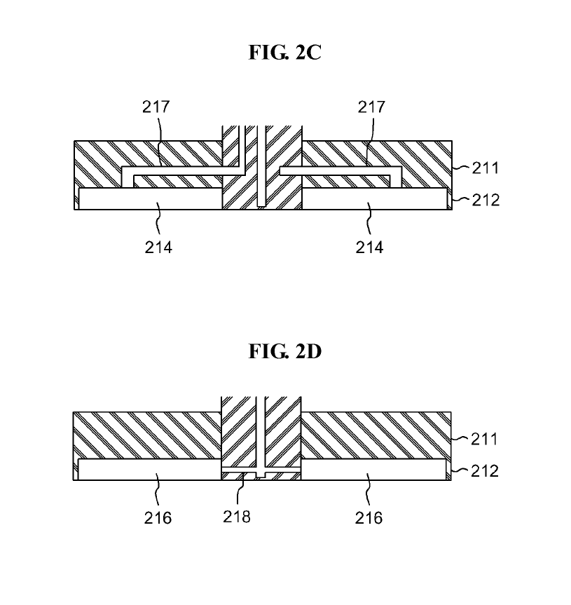

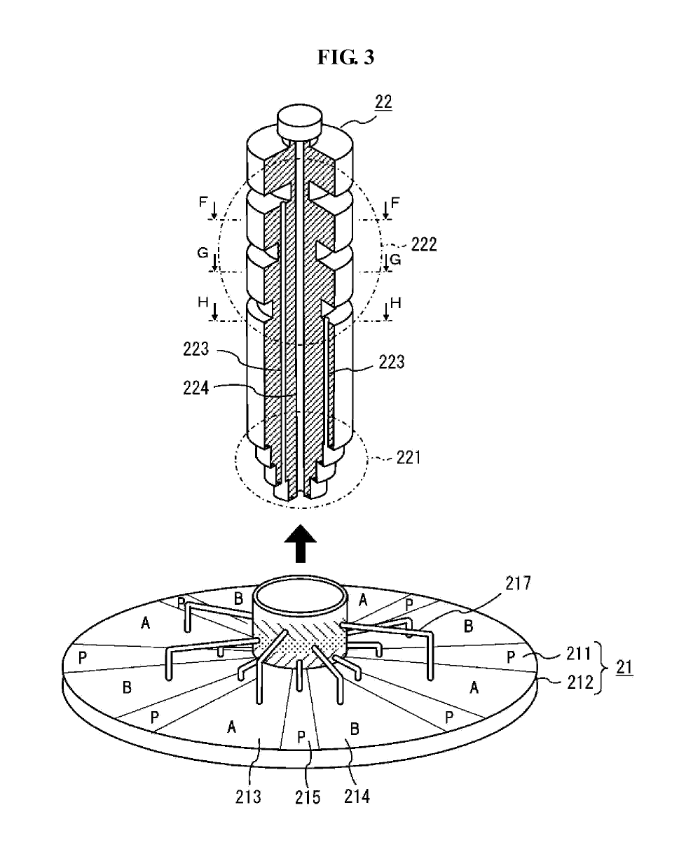

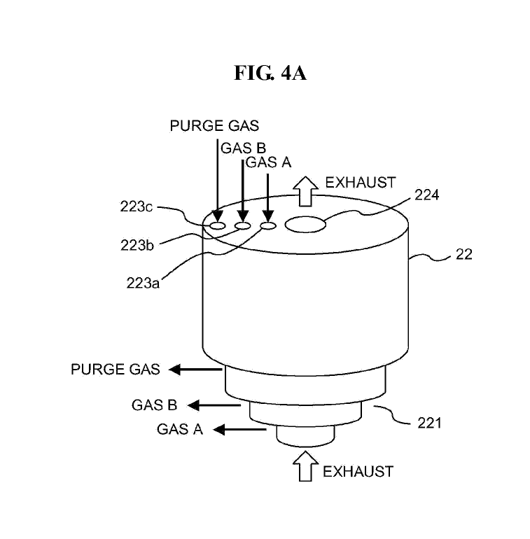

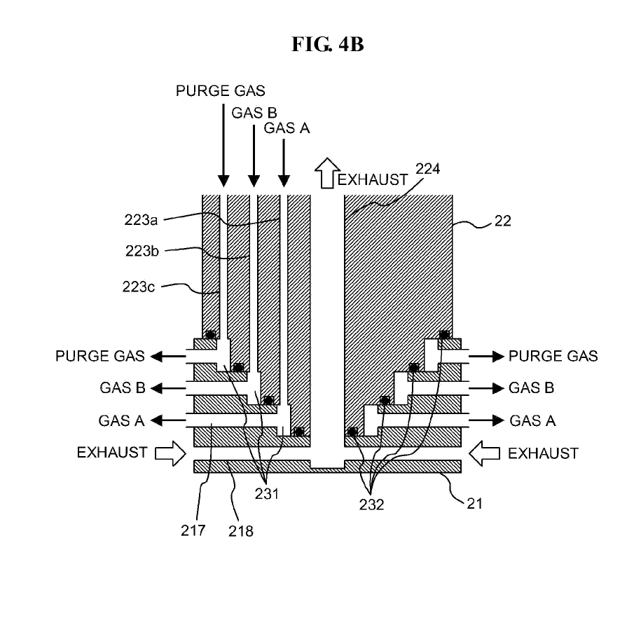

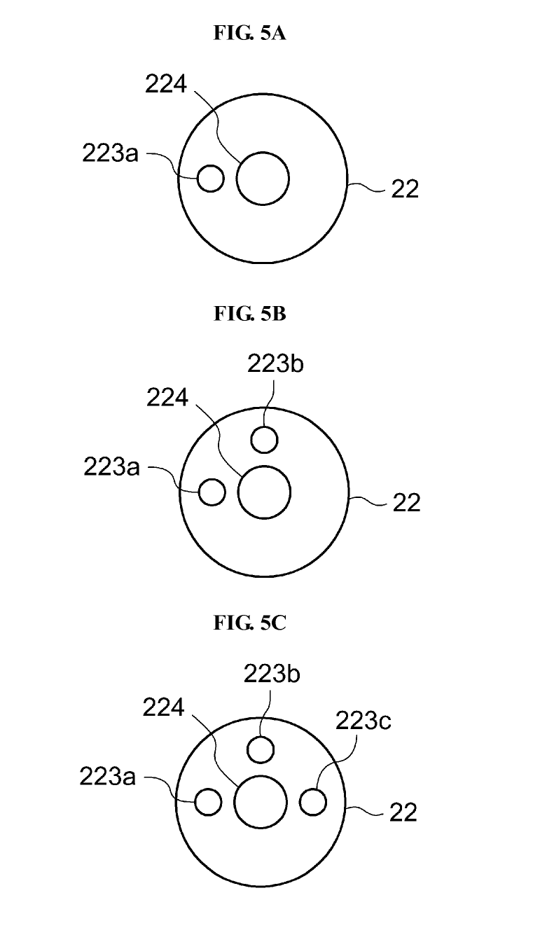

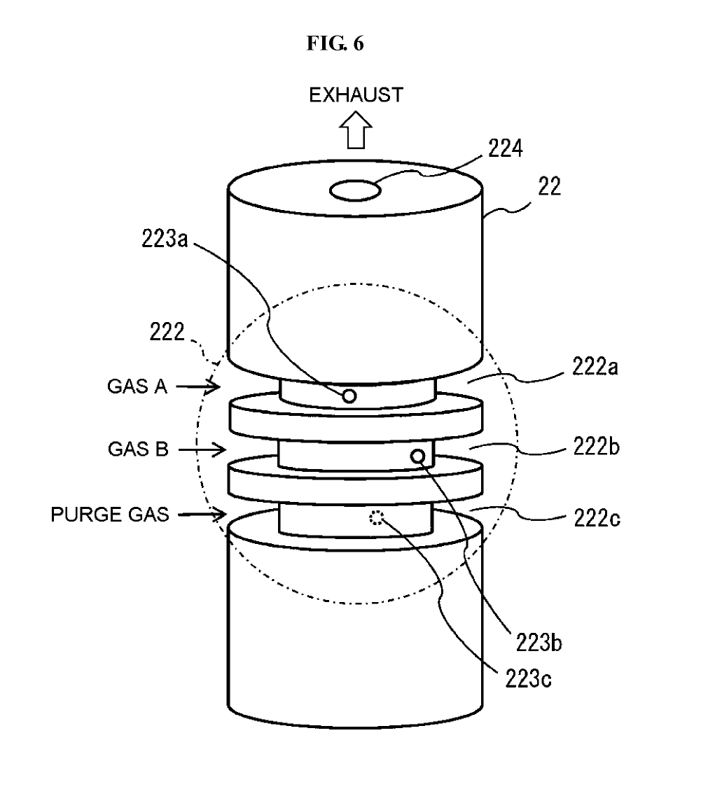

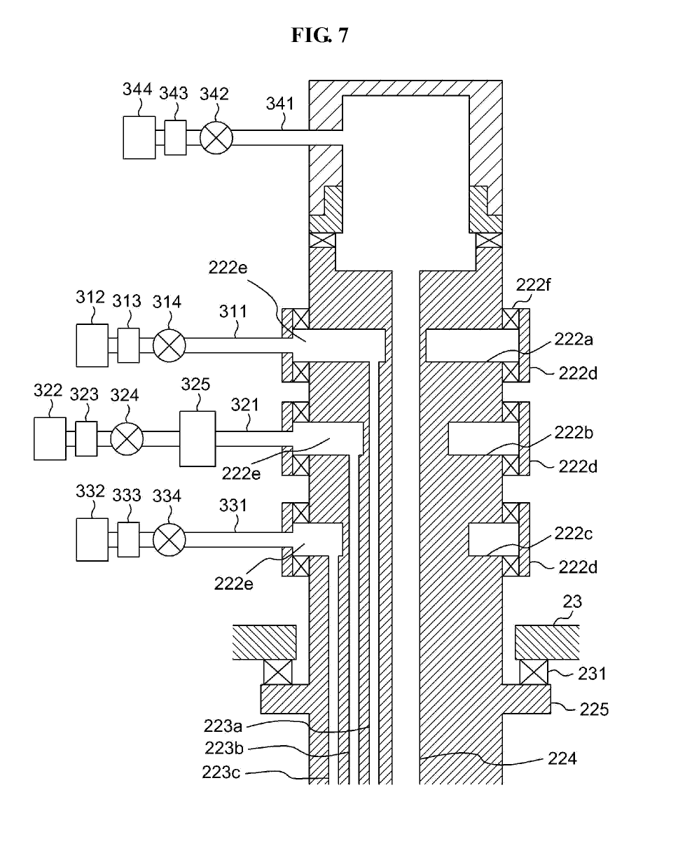

Hereinafter, a configuration of the substrate processing apparatus according to the embodiment will be described with reference to FIGS. 1 through 7. FIG. 1 is a view for schematically showing a schematic configuration example of a major part of the substrate processing apparatus according to the embodiment, FIGS. 2A through 2D are views for describing a configuration example of a gas supply plate included in the substrate processing apparatus according to the embodiment, FIG. 3 is a perspective view showing another configuration example of the gas supply plate included in the substrate processing apparatus according to the embodiment and a configuration example of a gas introduction shaft included in the substrate processing apparatus, FIGS. 4A and 4B are views for describing a configuration example of a fitting step section in the gas introduction shaft included in the substrate processing apparatus according to the embodiment, FIGS. 5A through 5C are views for describing a configuration example of a gas introduction pipe of the gas introduction shaft included in the substrate processing apparatus according to the embodiment, FIG. 6 is a view for describing a configuration example of a gas supply groove section in the gas introduction shaft included in the substrate processing apparatus according to the embodiment, and FIG. 7 is a conceptual view schematically showing a configuration example of the gas introduction shaft and a gas pipe of the substrate processing apparatus according to the embodiment.

### (Processing Container)

The substrate processing apparatus described in the embodiment includes a processing container (not shown). The processing container is constituted by a sealed container formed of a metal material such as aluminum (Al), stainless steel (SUS), or the like. In addition, a substrate loading outlet (not shown) is installed at a side surface of the processing container, and a wafer is conveyed via the substrate loading outlet. In addition, a gas exhaust system such as a vacuum pump, a pressure controller or the like (not shown) is connected to the processing container, and the inside of the processing container can be adjusted to a predetermined pressure using the gas exhaust system.

### (Substrate Support Unit)

As shown in FIG. 1, a substrate support unit 10 on which a wafer W is placed is installed in the processing container. The substrate support unit 10 is formed in, for example, a disk shape, and is configured such that the plurality of wafers W are placed on an upper surface thereof (a substrate engaging surface) in a circumferential direction at equal intervals. In addition, the substrate support unit 10 includes a heater (not shown) serving as a heating source, and is configured to maintain a temperature of the wafer W at a predetermined temperature using the heater. In addition, while FIG. 1 shows the case in which five wafers W are loaded, the present invention is not limited thereto and any number of wafers may be loaded when appropriately configured. For example, when the number of loaded wafers is large, improvement of processing throughput can be expected, and when the number of loaded wafers is small, an increase in the size of the substrate support unit 10 can be suppressed. Since the substrate engaging surface of the substrate support unit 10 comes in direct contact with the wafer W, the substrate support unit 10 may be formed of a material such as quartz, alumina or the like.

The substrate support unit 10 is configured to be rotatable in a state in which the plurality of wafers W are placed thereon. Specifically, the substrate support unit 10 is configured to be rotatably driven by a rotary driving mechanism (not shown) about a center of a disk as an axis of rotation. The rotary driving mechanism may be configured to include, for example, a bearing of a rotary shaft configured to rotatably support the substrate support unit 10 and a driving source represented by an electric motor, or the like.

In addition, here, while the case in which the substrate support unit 10 is rotatably configured has been exemplarily described, when a relative position between each of the wafers W on the substrate support unit 10 and a cartridge head 20 (to be described below) can be moved, the cartridge head 20 may be configured to rotate. When the substrate support unit 10 is configured to be rotatable, complication of a configuration of a gas pipe or the like (to be described below) can be suppressed unlike the case in which the cartridge head 20 is rotated. On the other hand, when the cartridge head 20 is rotated, the moment of inertia applied to the wafer W can be suppressed and a rotational speed can be increased in comparison with the case in which the substrate support unit 10 is rotated.

### (Cartridge Head)

In addition, in the processing container, the cartridge head 20 is installed over the substrate support unit 10. The cartridge head 20 is configured to supply various gases (a source gas, a reactive gas, or a purge gas) onto the wafer W on the substrate support unit 10 from above and exhaust the various supplied gases to the above.

In order to perform the upward supply/upward exhaust of the various gases, the cartridge head 20 includes a gas supply plate 21 corresponding to the substrate support unit 10 and having a circular shape when seen in a plan view, and a gas introduction shaft 22 passing through the processing container from the gas supply plate 21 and extending to the outside of the container. In addition, the cartridge head 20 is configured such that the gas supply plate 21 is detachably mounted on the gas introduction shaft 22, which will be described below in detail. In addition, both the gas supply plate 21 and the gas introduction shaft 22 constituting the cartridge head 20 are formed of a metal material such as Al, SUS or the like, or a ceramic material such as quartz, alumina or the like.

### (Gas Supply Plate)

The gas supply plate 21 is used to supply various gases into the processing space formed on the substrate support unit 10. Accordingly, the gas supply plate 21 includes a disk-shaped processing space ceiling plate 211 opposite to the substrate support unit 10, and a cylindrical outer tube 212 extending from an outer circumferential edge of the processing space ceiling plate 211 toward the substrate support unit 10. In addition, the processing space for performing the processing of the wafer W placed on the substrate support unit 10 is formed between the processing space ceiling plate 211 surrounded by the outer tube 212 and the substrate support unit 10.

The processing space formed on the substrate support unit 10 by the gas supply plate 21 is divided into a plurality of gas supply regions (see reference characters A, B and P). Specifically, for example, as shown in FIG. 2A, the plurality of gas supply regions include two or more source gas supply regions 213 (see reference character A) and two or more reactive gas supply regions 214 (see reference character B) (specifically, each of the numbers is four), and inert gas supply regions 215 (see reference character P) between the source gas supply regions 213 and the reactive gas supply regions 214. As described below, a source gas serving as one of the processing gases is supplied into the source gas supply region 213 to provide a source gas atmosphere. A reactive gas serving as another one of the processing gases is supplied into the reactive gas supply region 214 to provide a reactive gas atmosphere. An inert gas serving as a purge gas is supplied into the inert gas supply region 215 to provide an inert gas atmosphere. Predetermined processing is performed on the wafer W according to the gases supplied into the regions 213 through 215 in the processing space divided as described above. In addition, when the reactive gas is excited to a plasma state, the inside of the reactive gas supply region 214 becomes the reactive gas atmosphere in the plasma state or the activated reactive gas atmosphere.

In order to divide the processing space into the regions 213 through 215, exhaust regions 216 disposed to radially extend from an inner circumferential side toward an outer circumferential side of the processing space ceiling plate 211 are formed between the regions 213 through 215. As described below, the exhaust region 216 is connected to a gas exhaust pipe 218. In addition, a boundary plate may be installed at a region of the exhaust region 216. The boundary plate is installed to extend from the processing space ceiling plate 211 toward the substrate support unit 10, and disposed to approach the substrate support unit 10 such that a lower end thereof does not interfere with the wafer W on the substrate support unit 10. Accordingly, amounts of gases passing between the boundary plate and the substrate support unit 10 are reduced, and thus, the gases are suppressed from being mixed between each of the regions 213 through 215.

As shown in FIG. 2B or 2C, a gas distribution pipe 217 is connected to each of the regions 213 through 215 divided by the exhaust region 216, and is formed such that the gas is supplied through the gas distribution pipe 217. That is, the gas distribution pipes 217 (the same number of gas distribution pipes 217 as the gas supply regions 213 through 215) connected to the plurality of gas supply regions 213 through 215 are installed in the gas supply plate 21. In addition, as shown in FIG. 2B or 2C, while the gas distribution pipe 217 may be disposed to be installed in the processing space ceiling plate 211, the gas distribution pipe 217 is not limited thereto but may be disposed to be exposed on the processing space ceiling plate 211 as shown in FIG. 3.

In addition, as shown in FIG. 2D, the gas exhaust pipes 218 in respective communication with the plurality of exhaust regions 216 are installed in the gas supply plate 21, and the gas in the exhaust regions 216 is exhausted through the gas exhaust pipes 218. The gas exhaust pipes 218 are installed to be disposed at inner circumferential sides of the exhaust regions 216. In addition, the gas exhaust pipes 218 are formed to join as one around a center of the gas supply plate 21 and the joined pipe extends upward.

In addition, the exhausting is not performed by the gas exhaust pipe 218 only, but an exhaust pipe may also be separately installed to exhaust the entire inside of the substrate processing apparatus.

### (Gas Introduction Shaft)

The gas introduction shaft 22 is used to introduce various gases into the processing space formed on the substrate support unit 10. Accordingly, as shown in FIG. 3, the gas introduction shaft 22 is formed in a columnar shaft shape to be concentric with the gas supply plate 21. In addition, a lower part of the gas introduction shaft 22 includes a fitting step section 221 for mounting the gas supply plate 21. In addition, an upper part of the gas introduction shaft 22 includes a gas supply groove section 222 for performing gas supply from the outside. In addition, a plurality of gas introduction pipes 223 and a gas exhaust pipe 224 provided at the axial center of the gas introduction shaft 22 are provided within the fitting step section 221 and the gas supply groove section 222.

### (Fitting Step Section)

As shown in FIG. 4A, the fitting step section 221 has a plurality of short columnar sections having different diameters and disposed to overlap on the same axis, and has a structure including a plurality of steps having convex shapes protruding downward. The number of stages of the step section corresponds to the number of types of gases supplied onto the wafer W on the substrate support unit 10 by the gas supply plate 21. For example, when three types of gases including the source gas, the reactive gas and the purge gas are supplied onto the wafer W, the step section having the three stages is also provided at the fitting step section 221.

The fitting step section 221 including the steps having the plurality of stages is fitted into a groove-shaped step portion formed in the gas supply plate 21 as shown in FIG. 4B to mount the gas supply plate 21. That is, the groove-shaped step portion corresponding to the step section having the plurality of stages included in the fitting step section 221 is formed in the gas supply plate 21. In addition, as the protrusion-shaped step portion of the fitting step section 221 of the gas introduction shaft 22 is fitted into the groove-shaped step portion of the gas supply plate 21, the gas supply plate 21 is mounted on the gas introduction shaft 22. As described below in detail, the fitting step section 221 serves as a standardized interface when the gas supply plate 21 is mounted on the gas introduction shaft 22.

In addition, a mounting state of the gas introduction shaft 22 and the gas supply plate 21 is maintained by a clamp (not shown, a detachment/attachment mechanism). Since the clamp may be realized using a known technique using a fastener such as a bolt, a nut or the like, detailed description thereof will be omitted. In addition, as the fixation by the clamp is released, the gas supply plate 21 can be separated from the gas introduction shaft 22. That is, the gas supply plate 21 is detachably mounted on the gas introduction shaft 22.

In addition, when the gas supply plate 21 is mounted on the gas introduction shaft 22, i.e., when the protrusion-shaped step portion of the fitting step section 221 of the gas introduction shaft 22 is fitted into the groove-shaped step portion of the gas supply plate 21, gas discharging spaces 231 serving as an annular space are formed between the step sections. Since the number of stages of the step section corresponds to the number of types of gases, the plurality of gas discharging spaces 231 corresponding to the number of types of gases are formed. Since the plurality of gas discharging spaces 231 are formed between the step sections, the plurality of gas discharging spaces 231 are formed to have different diameters on different planes.

A sealing member 232 such as an O ring is disposed in the vicinity of a place at which each of the gas discharging spaces 231 is formed. Accordingly, each of the gas discharging spaces 231 is hermetically sealed by the sealing member 232 to prevent generation of a leakage. The sealing member 232 is disposed on a surface parallel to the substrate engaging surface of the substrate support unit 10 on the fitting step section 221 of the gas introduction shaft 22 (i.e., a surface opposite to the substrate engaging surface), i.e., a coupling surface of the gas introduction shaft 22 and the gas supply plate 21. However, the sealing member 232 does not necessarily need to be disposed at the gas introduction shaft 22 side, and may be disposed at least one side of the gas introduction shaft 22 and the gas supply plate 21.

The gas distribution pipes 217 and gas introduction pipes 223a through 223c are connected to the gas discharging spaces 231 sealed by the sealing members 232, respectively. For example, the gas distribution pipe 217 is connected to a sidewall section of an outer circumferential side of the gas discharging space 231. When the plurality of gas supply regions 213 through 215 configured to supply the same type of gas are provided, the plurality of gas distribution pipes 217 are connected to the plurality of corresponding positions of the gas discharging space 231. In addition, the gas introduction pipes 223a through 223c are connected to, for example, a ceiling section of the gas discharging space 231. At least one of the gas introduction pipes 223a through 223c may be connected to one gas discharging space 231. In addition, the gas introduction pipes 223a through 223c extend upward from the gas discharging space 231 to reach the gas supply groove section 222. When the gas supply plate 21 is mounted on the gas introduction shaft 22 by the above-described configuration, the gas introduction pipes 223a through 223c of the gas introduction shaft 22 is connected to the gas distribution pipes 217 of the gas supply plate 21 via the annular gas discharging space 231.

The different types of gases (for example, one of the source gas, the reactive gas and the purge gas) flow through the gas introduction pipes 223a through 223c extending upward from the gas discharging spaces 231 such that the different types of gases are individually introduced into the gas discharging spaces 231. For example, as shown in FIGS. 4A and 4B, the gas introduction pipes 223a through 223c may be disposed parallel in a circumferential array in a radial direction of the gas introduction shaft 22. When disposed as described above, the gas introduction pipes 223a through 223c can easily correspond to the gas discharging spaces 231 or gas supply spaces 222e (to be described below). However, the embodiment is not limited to the above-described disposition, but for example, as shown in FIGS. 5A through 5C, the gas introduction pipes 223a through 223c may be disposed to be distributed in different positions at the same circumference of the gas introduction shaft 22. When distributed and disposed as described above, conductance of the gas introduction pipes 223a through 223c can be increased, and thus, a gas flow rate can be increased.

In addition, as shown in FIG. 4B, the gas exhaust pipe 224 installed at an axial center of the gas introduction shaft 22 is installed to pass through a lower end surface of the fitting step section 221, and is configured to come in communication with the joined section of the gas exhaust pipes 218 in the gas supply plate 21 when the gas supply plate 21 is mounted on the gas introduction shaft 22. When the gas exhaust pipe 224 is installed at the axial center of the gas introduction shaft 22 as described above, the diameter of the gas exhaust pipe 224 is easily increased, and as a result, exhaust conductance of the gas exhaust pipe 224 can be maximized.

### (Gas Supply Groove Section)

As shown in FIG. 6, the gas supply groove section 222 includes a plurality of groove sections 222a through 222c formed in an outer circumferential surface of a column of the gas introduction shaft 22, and each of the groove sections 222a through 222c is disposed to be arranged in an axial direction of the shaft of the gas introduction shaft 22. The installation number of groove sections 222a through 222c corresponds to the number of types of gases supplied onto the wafer W on the substrate support unit 10 by the gas supply plate 21. For example, when three types of gases including the source gas, the reactive gas and the purge gas are supplied onto the wafer W, the gas supply groove section 222 is configured to include the three groove sections 222a through 222c.

An upper end of each of the gas introduction pipes 223a through 223c is connected to each of the groove sections 222a through 222c. At least one of the gas introduction pipes 223a through 223c may be connected to each of the groove sections 222a through 222c. When the gas introduction pipes 223a through 223c are distributed and disposed, for example, in different positions at the same circumference of the gas introduction shaft 22 (for example, see FIGS. 5A through 5C), as shown in FIG. 6, the gas introduction pipes 223a through 223c may be disposed to be connected to inner circumferential side wall surfaces (i.e., wall surfaces that become groove bottoms) of the groove sections 222a through 222c. However, the gas introduction pipes 223a through 223c are not limited to the above-described disposition, for example, when the gas introduction pipes 223a through 223c are arranged and disposed in a radial direction of the column of the gas introduction shaft 22 (for example, see FIG. 4B), as shown in FIG. 7, the gas introduction pipes 223a through 223c may be disposed to be connected to wall surfaces of lower sides of the groove sections 222a through 222c.

As shown in FIG. 7, lid members 222d configured to close the groove sections 222a through 222c throughout the entire circumference are disposed at the outer circumferential sides of the groove sections 222a through 222c. Accordingly, the gas supply spaces 222e serving as annular spaces surrounded by the groove sections 222a through 222c and the lid members 222d are formed in the groove sections 222a through 222c. For example, any one of the source gas, the reactive gas and the purge gas is supplied into each of the gas supply spaces 222e, which will be described below. That is, gas introduction into the gas introduction pipes 223a through 223c from the outside via the gas supply spaces 222e is performed in the gas supply groove section 222.

A magnetic fluid seal 222f is disposed between the lid member 222d that forms the gas supply space 222e and the outer circumferential surface of the column of the gas introduction shaft 22. Accordingly, the gas introduction shaft 22 is configured such that lid members 222d configured to close the groove sections 222a through 222c can be rotated about the shaft center serving as a rotary shaft in a fixed state. In addition, the magnetic fluid seal 222f should not be disposed when the substrate support unit 10 rather than the cartridge head 20 is rotated for relative position movement of the substrate support unit 10 and the cartridge head 20.

In addition, when the cartridge head 20 is configured to be rotated for relative position movement of the substrate support unit 10 and the cartridge head 20, a magnetic fluid seal 231 is also disposed between a processing container ceiling section 23 through which the gas introduction shaft 22 passes and a flange section 225 installed at the outer circumferential surface of the column of the gas introduction shaft 22.

### (Gas Supply/Exhaust System)

A gas supply/exhaust system configured to perform supply/exhaust of various gases onto/from the wafer W on the substrate support unit 10 and described as shown in FIG. 7 is connected to the gas introduction shaft 22 as described above.

### (Processing Gas Supply Unit)

A source gas supply pipe 311 is connected to the lid member 222d configured to close the groove section 222a of the gas supply groove section 222. A source gas supply source 312, a mass flow controller (MFC) 313 serving as a flow rate controller (a flow rate control unit) and a valve 314 serving as an opening/closing valve are installed at the source gas supply pipe 311 in sequence from an upstream direction. A source gas is supplied into the gas supply space 222e formed by the lid member 222d to which the source gas supply pipe 311 is connected by the above-described configuration. The supplied source gas is introduced into the gas introduction pipe 223a via the gas supply space 222e.

The source gas is one of the processing gases supplied onto the wafer W, for example, a source gas (i.e., TiCl₄ gas) obtained by vaporizing TiCl₄ (titanium tetrachloride) serving as a metal liquid source material including the element titanium (Ti). The source gas may be any one of a solid, a liquid and a gas at a normal temperature and a normal pressure. When the source gas is the liquid at the normal temperature and the normal pressure, a vaporizer (not shown) may be installed between the source gas supply source 312 and the MFC 313. In addition, a heater may be installed to heat entire part from the source gas supply source 312 to the gas introduction shaft 22, and may be configured to maintain a vaporized state of the gas. Here, the source gas will be described as a gas.

In addition, a gas supply system (not shown) configured to supply an inert gas serving as a carrier gas of a source gas may be connected to the source gas supply pipe 311. The inert gas serving as the carrier gas may include, for example, specifically, nitrogen (N₂) gas. In addition, in addition to N₂ gas, for example, a rare gas such as helium (He) gas, neon (Ne) gas, argon (Ar) gas or the like may be used.

Mainly, a processing gas supply unit is constituted by the source gas supply pipe 311, the MFC 313 and the valve 314. In addition, the source gas supply source 312 may be added to the configuration of the processing gas supply unit.

### (Reactive Gas Supply Unit)

In addition, a reactive gas supply pipe 321 is connected to the lid member 222d configured to close the groove section 222b of the gas supply groove section 222, i.e., the lid member 222d disposed in the vicinity of the lid member 222d to which the source gas supply pipe 311 is connected. A reactive gas supply source 322, a mass flow controller (MFC) 323 serving as a flow rate controller (a flow rate control unit) and a valve 324 serving as an opening/closing valve are installed at the reactive gas supply pipe 321 in sequence from the upstream direction. The reactive gas is supplied into the gas supply space 222e formed by the lid member 222d to which the reactive gas supply pipe 321 is connected according to the above-described configuration. In addition, the supplied reactive gas is introduced into the gas introduction pipe 223b via the gas supply space 222e.

The reactive gas is another one of the processing gases supplied onto the wafer W, and for example, ammonia (NH₃) gas is used.

In addition, a gas supply system (not shown) configured to supply an inert gas serving as a carrier gas or a dilution gas of the reactive gas may be connected to the reactive gas supply pipe 321. The inert gas considered to be used as the carrier gas or the dilution gas includes, specifically, for example, N₂ gas, but in addition to N₂ gas, for example, a rare gas such as He gas, Ne gas, Ar gas or the like may be used.

Mainly, a reactive gas supply unit is constituted by the reactive gas supply pipe 321, the MFC 323 and the valve 324. In addition, the reactive gas supply source 322 may be added to the configuration of the reactive gas supply unit. In addition, a remote plasma unit (RPU) 325 may be installed at a rear stage of the valve 324 such that the reactive gas can be excited to a plasma state and then is supplied.

### (Inert Gas Supply Unit)

An inert gas supply pipe 331 is connected to the lid member 222d configured to close the groove section 222c of the gas supply groove section 222, i.e., the lid member 222d disposed in the vicinity of the lid member 222d to which the reactive gas supply pipe 321 is connected. An inert gas supply source 332, a mass flow controller (MFC) 333 serving as a flow rate controller (a flow rate control unit) and a valve 334 serving as an opening/closing valve are installed at the inert gas supply pipe 331 in sequence from the upstream direction. An inert gas is supplied into the gas supply space 222e formed by the lid member 222d to which the inert gas supply pipe 331 is connected according to the above-described configuration. In addition, the supplied inert gas is introduced into the gas introduction pipe 223c via the gas supply space 222e.

The inert gas serves as a purge gas such that the source gas and the reactive gas are not mixed on a surface of the wafer W. Specifically, for example, N₂ gas may be used. In addition, in addition to N₂ gas, for example, a rare gas such as He gas, Ne gas, Ar gas or the like may be used.

Mainly, an inert gas supply unit is constituted by the inert gas supply pipe 331, the inert gas supply source 332, the MFC 333 and the valve 334.

### (Gas Exhaust Unit)

A gas exhaust pipe 341 is connected to the vicinity of an upper end of the gas exhaust pipe 224 installed at the shaft center of the gas introduction shaft 22. A valve 342 is installed at the gas exhaust pipe 341. In addition, a pressure controller 343 configured to control the inside of the processing space to a predetermined pressure is installed at the gas exhaust pipe 341 at a downstream side of the valve 342. In addition, a vacuum pump 344 is installed at the gas exhaust pipe 341 at a downstream side of the pressure controller 343. Gas exhaust from the inside of the gas exhaust pipe 224 to the outside of the gas introduction shaft 22 is performed by the above-described configuration. In addition, an exhaust pipe configured to exhaust the entire inside of the substrate processing apparatus is also joined to the valve 342, or a valve may be separately installed to be joined to the vacuum pump 344.

Mainly, a gas exhaust unit is constituted by the gas exhaust pipe 341, the valve 342, the pressure controller 343 and the vacuum pump 344.

### (Controller)

In addition, as shown in FIG. 1, the substrate processing apparatus according to the embodiment includes a controller 40 configured to control operations of parts of the substrate processing apparatus. The controller 40 includes at least a calculation unit 401 and a storage unit 402. The controller 40 is connected to the above-described configuration, and the controller 40 calls a program or a recipe from the storage unit 402 according to a user's instruction and controls operations of the configurations according to contents thereof. Specifically, the controller 40 controls operations of the heater, the rotary driving mechanism, the MFCs 313, 323 and 333, the valves 314, 324, 334 and 342, the RPU 325, the pressure controller 343, the vacuum pump 344, and so on.

In addition, the controller 40 may be constituted by a dedicated computer, or may be constituted by a general-purpose computer. For example, the controller 40 according to the embodiment may be configured by preparing an external storage device 41 in which the above-described program is stored (for example, a magnetic tape, a magnetic disk such as a flexible disk, a hard disk or the like, an optical disc such as a CD, DVD or the like, an optical magnetic disk such as an MO, a semiconductor memory such as a USB memory, a memory card or the like), and installing the program in the general-purpose computer using the external storage device.

In addition, a means configured to supply a program to the computer is not limited to the case in which the program is supplied via the external storage device 41. For example, the program may be supplied using a communication means such as the Internet or an exclusive line without the external storage device 41. In addition, the storage unit 402 or the external storage device 41 is constituted by a non-transitory computer-readable recording medium. Hereinafter, these are generally and simply referred to as recording media. Further, the term “recording medium” used in the description may include only the storage unit 402, only the external storage device 41, or both of these.

### (2) Substrate Processing Process

Next, a process of forming a thin film on the wafer W using the substrate processing apparatus will be described as one process of a method of manufacturing a semiconductor device. In addition, in the following description, operations of the parts that constitute the substrate processing apparatus are controlled by the controller 40.

Here, an example in which TiCl₄ gas is obtained by vaporizing TiCl₄ to serve as the source gas (the first processing gas), NH₃ gas is used as the reactive gas (the second processing gas) and these gases are alternately supplied to form a TiN film serving as a metal thin film on the wafer W will be described.

### (Basic Processing Operation in Substrate Processing Process)

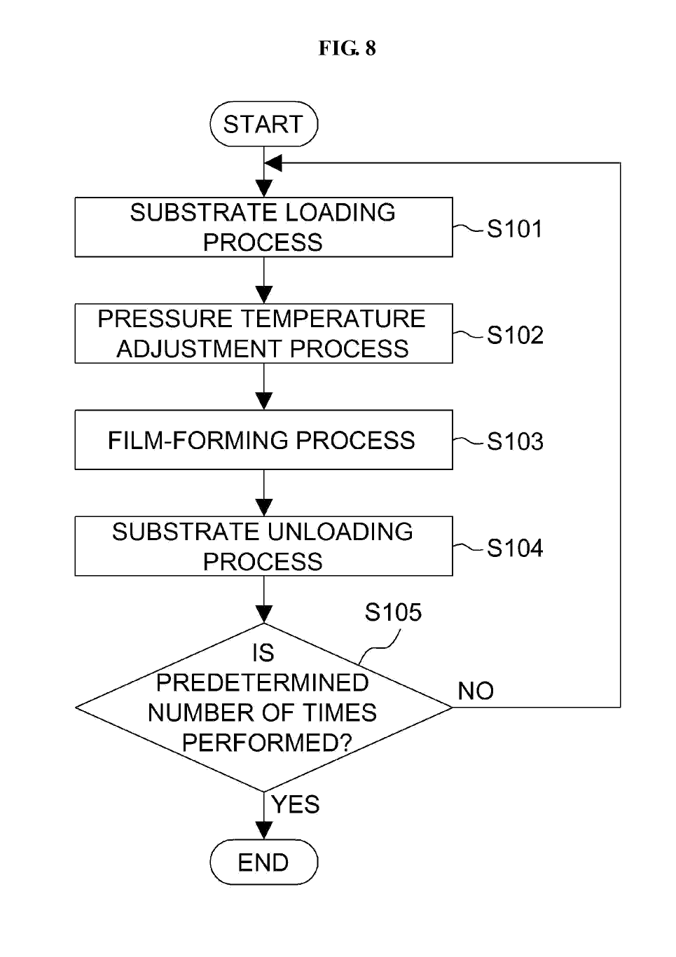

First, a basic processing operation in the substrate processing process of forming a thin film on the wafer W will be described. FIG. 8 is a flowchart showing the substrate processing process according to the embodiment.

### (Substrate Loading Process: S101)

In the substrate processing apparatus according to the embodiment, first, in a substrate loading process S101, the substrate loading outlet of the processing container is opened, the plurality of (for example, five) wafers W are loaded into the processing container using a wafer transfer device (not shown), and the wafers W are arranged and placed on the substrate support unit 10. In addition, the wafer transfer device is withdrawn to the outside of the processing container, and the substrate loading outlet is closed to close the inside of the processing container.

### (Pressure Temperature Adjustment Process: S102)

After the substrate loading process S101, a pressure temperature adjustment process S102 is performed. In the pressure temperature adjustment process S102, after the inside of the processing container is closed in the substrate loading process S101, the gas exhaust system (not shown) connected to the processing container is operated such that the inside of the processing container is controlled to become a predetermined pressure. The predetermined pressure is a processing pressure at which a TiN film can be formed in a film-forming process S103 (to be described below), and for example, a processing pressure at which the source gas supplied onto the wafer W is not decomposed. Specifically, the processing pressure is considered to be 50 Pa to 5,000 Pa. The processing pressure is also maintained in the film-forming process S103 (to be described below).

In addition, in the pressure temperature adjustment process S102, power is supplied to the heater embedded in the substrate support unit 10, and the surface of the wafer W is controlled to become a predetermined temperature. Here, the temperature of the heater is adjusted by controlling a current supply state to the heater based on temperature information detected by a temperature sensor (not shown). The predetermined temperature is a processing temperature at which the TiN film can be formed in the film-forming process S103, for example, a processing temperature at which the source gas supplied onto the wafer W is not decomposed. Specifically, the processing temperature is considered as a temperature of room temperature or more and 500° C. or less, preferably, room temperature or more and 400° C. or less. The processing temperature is also maintained in the film-forming process S103, which will be described below.

### (Film-Forming Process: S103)

After the pressure temperature adjustment process S102, the film-forming process S103 is performed. The processing operations performed in the film-forming process S103 are generally classified as a relative position movement processing operation and a gas supply exhaust processing operation. In addition, the relative position movement processing operation and the gas supply exhaust processing operation will be described below in detail.

### (Substrate Unloading Process: S104)

After the above-described film-forming process S103, a substrate unloading process S104 is performed. In the substrate unloading process S104, in reverse order of the case of the above-described substrate loading process S101, the processed wafer W is unloaded to the outside of the processing container using the wafer transfer device.

### (Processing Number Determination Process: S105)

After unloading the wafer W, the controller 40 determines whether the performed number of each of the series processes including the substrate loading process S101, the pressure temperature adjustment process S102, the film-forming process S103 and the substrate unloading process S104 reaches the predetermined number (S105). When it is determined that the performed number does not reach the predetermined number, the substrate loading process S101 is performed to start the processing of the next wafer W on standby. In addition, when it is determined that the performed number reaches the predetermined number, the series of processes are terminated after the cleaning process of the inside of the processing container or the like is performed according to necessity. In addition, since the cleaning process can be performed using the known technology, description thereof will be omitted.

### (Relative Position Movement Processing Operation)

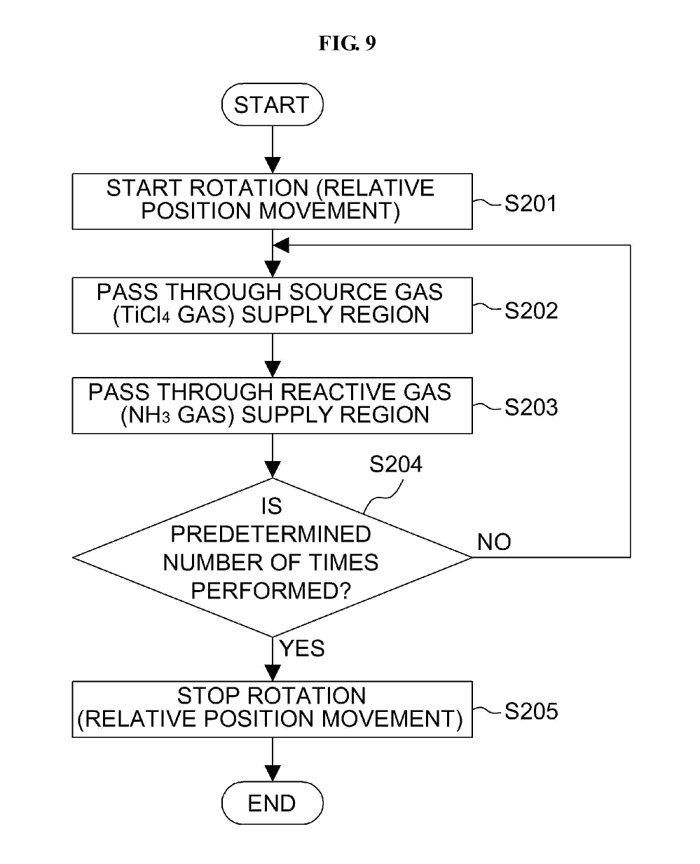

Next, the relative position movement processing operation performed in the film-forming process S103 will be described. The relative position movement processing operation is, for example, a processing operation of rotating the substrate support unit 10 and moving a relative position between the wafer W placed on the substrate support unit 10 and the cartridge head 20. FIG. 9 is a flowchart showing the relative position movement processing operation performed in the film-forming process of FIG. 8 in detail.

In the relative position movement processing operation performed in the film-forming process S103, first, as the substrate support unit 10 is rotated by the rotary driving mechanism, relative position movement between the substrate support unit 10 and the cartridge head 20 is started (S201). Accordingly, the wafers W placed on the substrate support unit 10 pass through the gas supply regions 213 through 215 of the gas supply plate 21 of the cartridge head 20 in sequence.

Here, the gas supply exhaust processing operation, which will be described below in detail, is started in the cartridge head 20. Accordingly, a source gas (TiCl₄ gas) is supplied into each of the source gas supply regions 213 in the gas supply plate 21, and a reactive gas (NH₃ gas) is supplied into each of the reactive gas supply regions 214.

Here, focusing on any one of the wafers W, as the substrate support unit 10 starts to rotate, the wafer W passes through the source gas supply region 213 (S202). Here, the source gas supply region 213 is adjusted to a processing pressure and a processing temperature at which the source gas is not decomposed. For this reason, when the wafer W passes through the source gas supply region 213, gas molecules of the source gas (TiCl₄ gas) are adsorbed onto the surface of the wafer W. In addition, a time during which the wafer W passes through the source gas supply region 213, i.e., a supply time of the source gas is adjusted to become, for example, 0.1 to 20 seconds.

Upon passing through the source gas supply region 213, the wafer W passes through the inert gas supply region 215 into which the inert gas (N₂ gas) is supplied, and then, continuously passes through the reactive gas supply region 214 (S203). Here, the reactive gas (NH₃ gas) is supplied into the reactive gas supply region 214. For this reason, when the wafer W passes through the reactive gas supply region 214, the reactive gas is uniformly supplied onto the surface of the wafer W and reacts with the gas molecules of the source gas adsorbed onto the wafer W to form a TiN film of less than one atomic layer (less than 1 Å) on the wafer W. A time during which the wafer W passes through the reactive gas supply region 214, i.e., a supply time of the reactive gas is adjusted to become, for example, 0.1 to 20 seconds.

In addition, in order to uniformly perform an initial TiCl₄—NH₃ cycle on all the wafers W, supply of the NH₃ gas into the reactive gas supply region 214 may be stopped until the wafer W passes through the source gas supply region 213 such that NH₃ is supplied after TiCl₄ is adsorbed onto all the wafers W.

In addition, the reactive gas may be excited to a plasma state using the RPU 325 to be supplied onto the wafer W. As the reactive gas is excited to the plasma state, processing at a low temperature becomes further possible.

An operation of passing through the source gas supply region 213 and an operation of passing through the reactive gas supply region 214 are set as one cycle, and the controller 40 determines whether the cycle is performed a predetermined number of times (n cycles) (S204). When the cycle is performed the predetermined number of times, a titanium nitride (TiN) film having a desired film thickness is formed on the wafer W. That is, in the film-forming process S103, a cyclic processing operation of repeating a process of alternately supplying different processing gases onto the wafer W by performing the relative position movement processing operation is performed. In addition, in the film-forming process S103, the TiN film is simultaneously and parallelly formed on the wafers W by performing the cyclic processing operation on the wafers W placed on the substrate support unit 10.

In addition, when the cyclic processing operation at the predetermined number of times is terminated, the controller 40 terminates rotary driving of the substrate support unit 10 by the rotary driving mechanism and stops the relative position movement of the substrate support unit 10 and the cartridge head 20 (S205). Accordingly, the relative position movement processing operation is terminated. In addition, when the cyclic processing operation at the predetermined number of times is terminated, the gas supply exhaust processing operation is also terminated.

### (Gas Supply Exhaust Processing Operation)

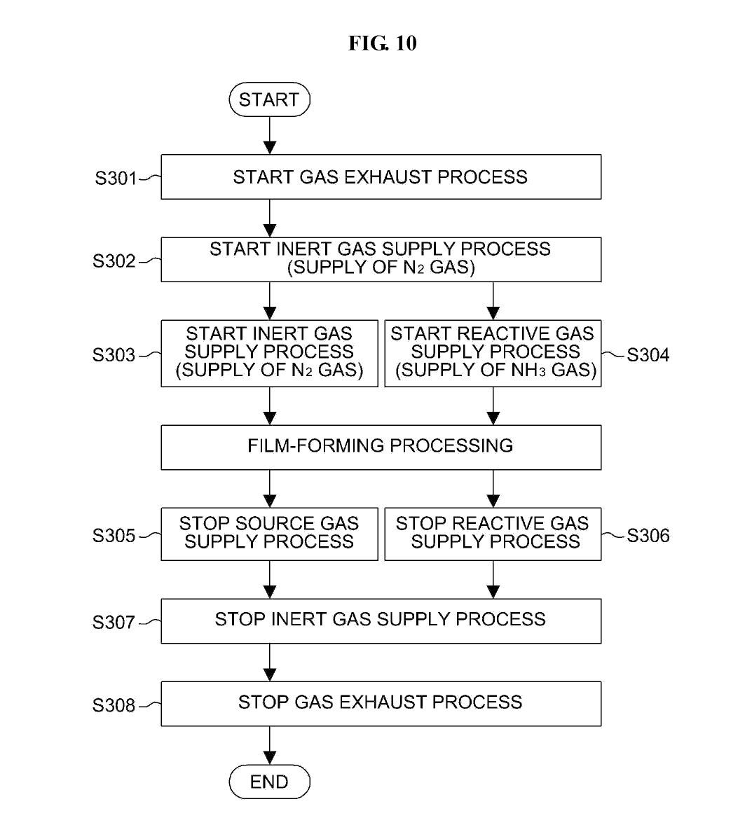

Next, the gas supply exhaust processing operation performed in the film-forming process S103 will be described. The gas supply exhaust processing operation is a processing operation of performing supply/exhaust of various gases onto the wafer W on the substrate support unit 10. FIG. 10 is a flowchart showing the gas supply exhaust processing operation performed in the film-forming process of FIG. 8 in detail.

In the gas supply exhaust processing operation performed in the film-forming process S103, first, a gas exhaust process S301 is started. In the gas exhaust process S301, the vacuum pump 344 is operated and the valve 342 is open. Accordingly, in the gas exhaust process S301, the gases in the gas supply regions 213 through 215 are exhausted from the exhaust regions 216 in the gas supply plate 21 to the outside of the processing container through the gas exhaust pipe 218 in communication with the exhaust regions 216, the gas exhaust pipe 224 of the gas introduction shaft 22 in communication with the joined portion of the gas exhaust pipes 218 and the gas exhaust pipe 341 connected to the position in the vicinity of the upper end of the gas exhaust pipe 224. Here, the pressures in the gas supply regions 213 through 215 and the exhaust region 216 are controlled to a predetermined pressure by the pressure controller 343. In addition, the gas diffused to the outside of the gas supply plate 21 is rapidly exhausted through an exhaust port through which the entire inside of the substrate processing apparatus is exhausted.

After the gas exhaust process S301 is started, an inert gas supply process S302 is started. In the inert gas supply process S302, the valve 334 of the inert gas supply pipe 331 is opened, and the MFC 333 is adjusted such that a flow rate becomes a predetermined flow rate. Accordingly, in the inert gas supply process S302, the inert gas (N₂ gas) is introduced into the gas introduction pipe 223c of the gas introduction shaft 22 via the gas supply space 222e to which the inert gas supply pipe 331 is connected, and the inert gas is supplied into the inert gas supply region 215 through the gas distribution pipe 217 in communication with the gas introduction pipe 223c via the gas discharging space 231. A supply flow rate of the inert gas is, for example, 100 sccm to 10,000 sccm. When the above-described inert gas supply process S302 is performed, an air curtain due to the inert gas is formed in the inert gas supply region 215 between the source gas supply region 213 and the reactive gas supply region 214.

After the inert gas supply process S302 is started, a source gas supply process S303 and a reactive gas supply process S304 are started.

In the source gas supply process S303, a source material (TiCl₄) is vaporized to generate (preliminarily vaporize) a source gas (i.e., TiCl₄ gas). Preliminary vaporization of the source gas may be parallelly performed with the substrate loading process S101, the pressure temperature adjustment process S102 or the like. This is because a predetermined time is needed to stably generate the source gas.

In addition, when the source gas is generated, in the source gas supply process S303, the valve 314 of the source gas supply pipe 311 is opened, and the MFC 313 is adjusted such that a flow rate becomes a predetermined flow rate. Accordingly, in the source gas supply process S303, a source gas (TiCl₄ gas) is introduced into the gas introduction pipe 223a of the gas introduction shaft 22 via the gas supply space 222e to which the source gas supply pipe 311 is connected, and the source gas is supplied into the source gas supply region 213 through the gas distribution pipe 217 in communication with the gas introduction pipe 223a via the gas discharging space 231. A supply flow rate of the source gas is, for example, 10 sccm to 3,000 sccm.

Here, an inert gas (N₂ gas) may be supplied as a carrier gas of the source gas. In this case, a supply flow rate of the inert gas is, for example, 10 sccm to 5,000 sccm.

When the above-described source gas supply process S303 is performed, the source gas (TiCl₄ gas) is uniformly diffused in the entire region of the source gas supply region 213. In addition, since the gas exhaust process S301 is already started, the source gas diffused in the source gas supply region 213 is exhausted from the source gas supply region 213 via the exhaust region 216 by the gas exhaust pipe 218 in communication with the exhaust region 216. In addition, an air curtain of the inert gas is formed in the neighboring inert gas supply regions 215 as the inert gas supply process S302 is started. For this reason, the source gas supplied into the source gas supply region 213 is not leaked to the neighboring inert gas supply regions 215 side from the exhaust region 216.

In addition, in the reactive gas supply process S304, the valve 324 of the reactive gas supply pipe 321 is opened, and the MFC 323 is adjusted such that a flow rate becomes a predetermined flow rate. Accordingly, in the reactive gas supply process S304, the reactive gas is introduced into the gas introduction pipe 223b of the gas introduction shaft 22 via the gas supply space 222e to which the reactive gas supply pipe 321 is connected, and the reactive gas is supplied into the reactive gas supply region 214 through the gas distribution pipe 217 in communication with the gas introduction pipe 223b via the gas discharging space 231. A supply flow rate of the reactive gas is, for example, 10 sccm to 10,000 sccm.

In addition, in order to uniformly perform the initial TiCl₄—NH₃ cycle on all the wafers W, supply of the NH₃ gas into the reactive gas supply region 214 may be stopped until all the wafers W pass through the source gas supply region 213 such that NH3 is supplied after TiCl₄ is absorbed onto all the wafers W.

In addition, the reactive gas (NH₃ gas) flowing through the reactive gas supply pipe 321 may be activated to generate plasma using the RPU 325, and the reactive gas in the plasma state may be supplied into the reactive gas supply region 214.

Here, the inert gas (N₂ gas) may be supplied as the carrier gas or the dilution gas of the reactive gas. In this case, a supply flow rate of the inert gas is, for example, 10 sccm to 5,000 sccm.

When the above-described reactive gas supply process S304 is performed, the reactive gas (NH₃ gas) is uniformly diffused in the entire region of the reactive gas supply region 214. In addition, since the gas exhaust process S301 is already started, the reactive gas diffused in the reactive gas supply region 214 is exhausted from the inside of the reactive gas supply region 214 via the exhaust region 216 by the gas exhaust pipe 218 in communication with the exhaust region 216. In addition, an air curtain of the inert gas is formed in the neighboring the inert gas supply regions 215 as the inert gas supply process S302 is started. For this reason, the reactive gas supplied into the reactive gas supply region 214 is not leaked to the neighboring inert gas supply regions 215 side from the exhaust region 216.

The above-described processes S301 through S304 are sequentially or parallelly performed during the film-forming process S103. However, while the start timing is considered to be performed in the above-described sequence to improve sealing properties by the inert gas, the start timing is not limited thereto. When there is no concern about an error of less than one atomic layer (1 Å) in the predetermined film thickness as a target, the processes S301 through S304 may be simultaneously started. However, since a difference in film thickness or film quality may occur in each of the wafers W depending on the gas initially adsorbed according to the type of film, the gas initially exposed to the wafer W may be similar as described above.

As the above-described processes S301 through S304 are parallelly performed, in the film-forming process S103, the wafers W placed on the substrate support unit 10 sequentially pass through the source gas supply region 213 which is a source gas atmosphere, and through the reactive gas supply region 214 which is a reactive gas atmosphere. In addition, since the inert gas supply region 215 and the exhaust region 216 which is an inert gas atmosphere are disposed between the source gas supply region 213 and the reactive gas supply region 214, the source gas and the reactive gas supplied onto the wafers W are not mixed.

When the gas supply exhaust processing operation is terminated, first, the source gas supply process is terminated (S305), and the reactive gas supply process is terminated (S306). In addition, after the inert gas supply process is terminated (S307), the gas exhaust process is terminated (S308). However, the termination timing of the processes S305 through S308 are also similar to the above-described start timing, and the processes S305 through S308 may be terminated at different times or may be simultaneously terminated.

### (3) Plate Mounting Process

Next, a plate mounting process performed as pre-processing of the above-described substrate processing process will be described.

The plate mounting process is a process of mounting the gas supply plate 21 on the gas introduction shaft 22. The plate mounting process is performed until no later than a start of the film-forming process S103.

### (Supply Times of Various Gases)

Here, the supply time during which various gases (specifically, the source gas or the reactive gas) are supplied onto the wafer W in the film-forming process S103 will be described. In the above-described film-forming process S103, a process of alternately supplying the source gas and the reactive gas onto the wafer W is repeated. In the thin film-forming processing by the above-described alternate supply method, times during which the wafer W is exposed to the source gas and the reactive gas are different according to the type of thin film to be formed. For this reason, in order to appropriately perform the thin film-forming processing by the alternate supply method, there is a need to deal with optimization of the time during which the wafer W is exposed to each of the processing gases.

The time during which the wafer W is exposed to each of the processing gases is determined according to the time during which the wafer W passes through the source gas supply region 213 and the reactive gas supply region 214. That is, the time during which the wafer W is exposed to each of the processing gases depends on a size of an area when a rotational speed of the substrate support unit 10 is constant and each of the gas supply regions 213 and 214 is seen in a plan view. In addition, the rotational speed of the substrate support unit 10 in the film-forming process S103 should be constant. When there is a response of adjusting the region passing speed of the wafer W (i.e., a rotational angular velocity of the substrate support unit 10), since the plurality of wafers W are placed on the substrate support unit 10 and the processing space formed by the gas supply plate 21 is divided into the plurality of gas supply regions 213 through 215, while the time for some wafers W may be optimized, for other wafers W, which are simultaneously and parallelly processed, the time may not be optimized.

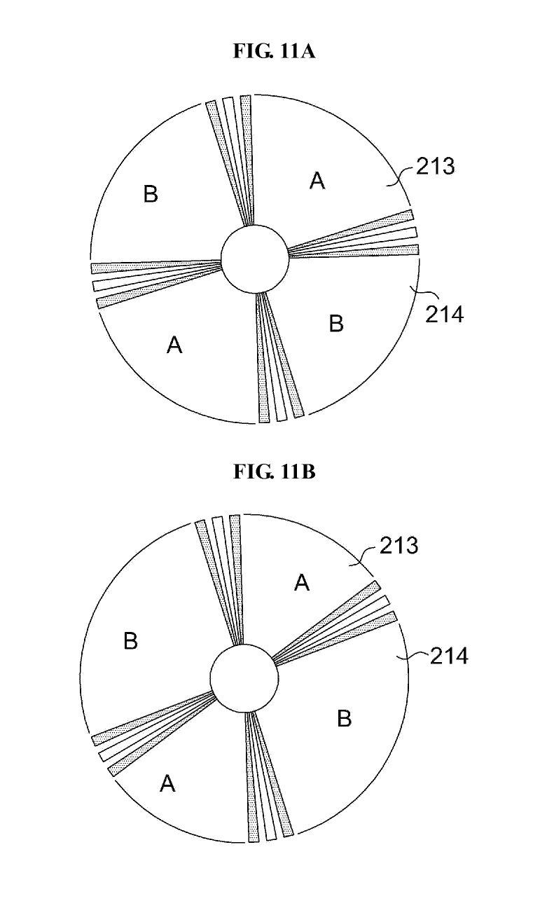

FIGS. 11A and 11B are views for describing an example of sizes of areas when the gas supply regions 213 and 214 of the gas supply plate 21 are seen in a plan view. In addition, in the exemplary drawings, for the purpose of easy understanding, the case in which the gas supply plate 21 includes two source gas supply regions 213 (reference character A of the drawings) and two reactive gas supply regions 214 (reference character B of the drawings) is shown.

In the example shown in FIG. 11A, positions of the exhaust regions 216 configured to separate the gas supply regions 213 and 214 are set such that the source gas supply regions 213 (reference character A of the drawings) and the reactive gas supply regions 214 (reference character B of the drawings) have the same area. In the above-described gas supply plate 21, the times during which the wafer W passes through the source gas supply region 213 and the reactive gas supply region 214, i.e., the times during which the wafer W is exposed to the source gas and the reactive gas become substantially equal. However, according to the type of thin film formed on the wafer W, there is no need to substantially equalize the times during which the wafer W is exposed to the source gas and the reactive gas, and the times may be appropriately different from each other. For example, in the example shown in FIG. 11B, the positions of the exhaust regions 216 that separate the gas supply regions 213 and 214 are set such that an area of the reactive gas supply region 214 (see reference character B of the drawings) is larger than an area of the source gas supply region 213 (see reference character A of the drawings). In the above-described the gas supply plate 21, a reaction amount of each of the gases can be increased by increasing a supply amount of the reactive gas onto the wafer W more than the source gas. On the other hand, the area of the reactive gas supply region 214 (see reference character B of the drawings) may be set appropriately smaller than the area of the source gas supply region 213 (see reference character A of the drawings).

That is, in the substrate processing apparatus for performing the thin film-forming processing by the alternate supply method, in order to appropriately perform the thin film-forming processing for various types of thin films, there is a need to deal with a variation in sizes of the gas supply regions 213 and 214.

However, in order to deal with the variation in sizes of the gas supply regions 213 and 214, individual preparation of different substrate processing apparatuses for the thin film-forming processing is not realistic in terms of cost, an installation space or the like. In addition, in order to deal with the variation in sizes of the processing regions, a mechanism configured to vary the sizes of the processing regions may be installed at the substrate processing apparatus. However, installation of such a mechanism may be difficult, and complex control processing may be needed to manage the operation of the mechanism.

Therefore, in the embodiment, in order to deal with the variation in sizes of the gas supply regions 213 and 214, the plate mounting process of mounting the gas supply plate 21 on the gas introduction shaft 22 is performed until no later than a start of the film-forming process S103.

### (Detailed Description of Plate Mounting Process)

Here, the plate mounting process will be described in detail. In the plate mounting process, the gas supply plate 21 to which the sizes of the gas supply regions 213 and 214 are appropriately set is previously prepared. When formation of the various types of thin films is assumed, the plurality of gas supply plates 21 appropriate for the various types of thin film-forming processing (i.e., the plurality of gas supply plates 21 to which the sizes of the gas supply regions 213 and 214 are set to be different from each other) may be previously prepared. In addition, one gas supply plate 21 appropriate for the type of thin film to be formed is selected from the plurality of gas supply plates 21, and the selected gas supply plate 21 is mounted on the gas introduction shaft 22. Specifically, the groove-shaped step portion formed in the selected gas supply plate 21 is fitted onto the protrusion-shaped step portion that constitutes the fitting step section 221 of the gas introduction shaft 22, and fixing this state by a clamp in is performed to maintain a mounting state of the gas introduction shaft 22 and the gas supply plate 21.

Here, in each of the gas supply plates 21 that should be previously prepared, the groove-shaped step portion is formed in a similar shape to be mounted on the gas introduction shaft 22. Accordingly, all the gas supply plates 21 can be completely identically mounted on the gas introduction shaft 22. That is, as an interface for mounting the gas supply plate 21 on the gas introduction shaft 22 is standardized, compatibility of each of the gas supply plates 21 can be secured.

When the gas supply plate 21 is mounted on the gas introduction shaft 22, the gas discharging space 231 serving as an annular space is formed between the protrusion-shaped step portion of the gas introduction shaft 22 and the groove-shaped step portion of the gas supply plate 21. In addition, the gas introduction pipes 223a through 223c of the gas introduction shaft 22 and the gas distribution pipes 217 of the gas supply plate 21 are connected to gas discharging spaces 231. That is, the gas distribution pipes 217 come in communication with the gas introduction pipes 223a through 223c via the annular gas discharging spaces 231. When the gas distribution pipes 217 come in communication with the gas introduction pipes 223a through 223c, the various gases introduced into the gas introduction pipes 223a through 223c are introduced into the gas distribution pipes 217 via the gas discharging spaces 231, and supplied into the gas supply regions 213 through 215 of the gas supply plate 21 through the gas distribution pipes 217.

Here, the annular gas discharging spaces 231 disposed between the gas introduction pipes 223a through 223c and the gas distribution pipes 217 serve as buffer spaces configured to isolate a flow of the gas in the gas introduction pipes 223a through 223c and a flow of the gas in the gas distribution pipe 217. For this reason, even when position precision of the gas introduction pipes 223a through 223c and the gas distribution pipes 217 is not strictly defined more than necessary, the gas introduction pipes 223a through 223c come in communication with the gas distribution pipes 217, and a smooth flow of the gas can be formed therebetween. In other words, even when a smooth flow of the gas is formed between the gas introduction pipes 223a through 223c of the gas introduction shaft 22 and the gas distribution pipes 217 of the gas supply plate 21, since a degree of freedom of each disposition position can be sufficiently secured, standardization of the mounting interface between the gas introduction shaft 22 and the gas supply plate 21 can be easily realized.

In addition, since the gas discharging space 231 serving as the buffer space is formed in an annular shape, the gas distribution pipes 217 may be connected to a plurality of positions at an outer circumference of the annulus. That is, the gases can be uniformly introduced into the gas distribution pipes 217 while connecting the plurality of gas distribution pipes 217 extending in different directions to one gas discharging space 231. Accordingly, even when each of the gas supply regions 213 through 215 is installed in the gas supply plate 21 as a plurality, various gases can be uniformly supplied into each of the gas supply regions 213 through 215.

In addition, the plurality of annular gas discharging spaces 231 are formed on different planes and to have different diameters to correspond to the number of types of gases. Accordingly, for example, even when three types of gases including the source gas, the reactive gas and the purge gas are supplied onto the wafer W, the various gases can be simultaneously and parallelly supplied into the gas supply regions 213 through 215.

In addition, since the gas discharging space 231 is hermetically sealed by the sealing member 232 in the mounted state of the gas introduction shaft 22 and the gas supply plate 21, a gas leakage does not occur even when the gas discharging space 231 serves as the buffer space for forming a smooth flow of the gas. The sealing member 232 that hermetically seals the gas discharging space 231 can facilitate the mounting of the gas supply plate 21 on the gas introduction shaft 22 when disposed on a surface opposite to the substrate engaging surface of the substrate support unit 10. For example, when the sealing member 232 is disposed on a circumferential surface of the column, while a sliding resistance may occur at a portion of the sealing member 232 when the gas supply plate 21 is mounted on the gas introduction shaft 22, generation of a sliding resistance due to the sealing member 232 can be avoided when the sealing member 232 is disposed at a surface opposite to the substrate engaging surface.

As a result, the plate mounting process of mounting the gas supply plate 21 on the gas introduction shaft 22 is terminated, and when the film-forming process S103 or the like is performed on a different type of thin film after the film-forming process S103 or the like is performed in the mounted state of the gas introduction shaft 22 and the gas supply plate 21, one gas supply plate 21 appropriate for the thin film-forming processing to be newly performed after the previously mounted gas supply plate 21 is separated from the gas introduction shaft 22 is selected, and the plate mounting process is performed again on the selected gas supply plate 21. That is, according to the type of thin film to be formed, the gas supply plate 21 mounted on the gas introduction shaft 22 is exchanged with another one.

Accordingly, in the embodiment, as the gas introduction shaft 22 and the gas supply plate 21, of which the mounting interface is standardized, are used, changing the sizes of the gas supply regions 213 through 215 can be easily or conveniently performed by simply exchanging the gas supply plate 21 with another one according to necessity, and thus, the times during which the wafer W is exposed to the processing gases can be optimized according to the types of thin films to be formed.

### (4) Effects of the Embodiment

According to the embodiment, one or a plurality of effects will be described as follows.

(a) According to the embodiment, the gas supply plate 21 is mounted on the gas introduction shaft 22, and while the gas supply plate 21 is mounted on the gas introduction shaft 22, the gas distribution pipes 217 of the gas supply plate 21 come in communication with the gas introduction pipes 223a through 223c of the gas introduction shaft 22 via the annular gas discharging spaces 231. For this reason, when the gas supply plate 21 mounted on the gas introduction shaft 22 is exchanged with another one, the sizes of the gas supply regions 213 through 215 of the gas supply plate 21 can be appropriately varied. That is, as the gas introduction shaft 22 and the gas supply plate 21, of which the mounting interface is standardized, are used, changing the sizes of the gas supply regions 213 through 215 can be easily or conveniently performed by simply exchanging the gas supply plate 21 with another one according to necessity. Accordingly, even when formation of the various types of thin films is assumed, the times during which the wafer W is exposed to the gases in the various types of thin film-forming processing can be optimized without individual preparation of a substrate processing apparatus for each thin film-forming processing or installation of a complex mechanism configured to vary the sizes of the gas supply regions 213 through 215 in the substrate processing apparatus.

(b) In addition, according to the embodiment, the plurality of annular gas discharging spaces 231 are formed when the gas supply plate 21 is mounted on the gas introduction shaft 22, and the plurality of annular gas discharging spaces 231 are formed on different planes with different diameters. That is, the plurality of annular gas discharging spaces 231 are formed in a step shape. For this reason, different types of gases can be simultaneously and parallelly supplied into the gas supply regions 213 through 215, respectively. In addition, since the plurality of gas distribution pipes 217 extending in different directions can be connected to one gas discharging space 231, even when the gas supply regions 213 through 215 into which the same type of gas should be supplied are provided at a plurality of positions, the gas can be uniformly supplied into the gas supply regions 213 through 215 at the plurality of positions.

(c) In addition, according to the embodiment, the sealing member 232 configured to hermetically seal the gas discharging space 231 is disposed on a surface parallel to the substrate engaging surface of the substrate support unit 10, i.e., the coupling surface between the gas introduction shaft 22 and the gas supply plate 21. For this reason, the gas discharging space 231 can be securely sealed to prevent generation of a gas leakage or the like while facilitating the mounting of the gas supply plate 21 on the gas introduction shaft 22.

(d) In addition, according to the embodiment, two or more source gas supply regions 213 and two or more reactive gas supply regions 214 serving as the plurality of gas supply regions 213 through 215 of the gas supply plate 21 are provided. As described above, when the two or more source gas supply regions 213 and the two or more reactive gas supply regions 214 are provided, processing throughput of the wafer W can be improved.

(e) In addition, according to the embodiment, in one of the gas supply plates 21 exchanged with another one in the plate mounting process, an area of a plane of the source gas supply region 213 is smaller than an area of a plane of the reactive gas supply region 214. When the gas supply plate 21 includes the above-described configuration, the reactive gas supply region 214 can be increased in comparison with the source gas supply region 213 when the gas supply plate 21 is used, and thus, a reaction rate of the source gas molecules supplied onto the wafer W can be improved.

(f) In addition, according to the embodiment, the plurality of gas supply regions 213 through 215 of the gas supply plate 21 including the inert gas supply region 215 disposed between the source gas supply region 213 and the reactive gas supply region 214 is provided. For this reason, even when the source gas is supplied onto the wafer W in the source gas supply region 213 and the reactive gas is supplied in the reactive gas supply region 214, the source gas and the reactive gas can be prevented from being mixed on the wafer W.

(g) In addition, according to the embodiment, the gas introduction shaft 22 on which the gas supply plate 21 is mounted is configured to include the gas exhaust pipe 224 at a center of the shaft. For this reason, when the gas exhaust from the gas supply regions 213 through 215 of the gas supply plate 21 is performed, exhaust conductance in the gas exhaust pipe 224 can be maximized, and thus, effective gas exhaust can be performed.

(h) In addition, according to the embodiment, the thin film-forming processing on the surface of the wafer W can be performed by moving the relative position between the cartridge head 20 including the gas introduction shaft 22 and the gas supply plate 21 and the substrate support unit 10 on which the wafer W is placed such that the wafer W sequentially passes through the gas supply regions 213 through 215. For this reason, for example, in comparison with the case in which the inside of the processing container is filled with the source gas or the reactive gas and these gases are alternately exchanged via the purge process, a consumption amount of the processing gas (the source gas or the reactive gas) can be suppressed, and thus, effective thin film-forming processing can be realized. That is, a maximum film-forming rate can be obtained with a minimum gas use amount.

(i) In addition, according to the embodiment, the gas introduction shaft 22 includes the annular gas supply space 222e, and the gas is introduced into the gas introduction pipes 223a through 223c from the outside via the gas supply spaces 222e. For this reason, the source gas supply pipe 311, the reactive gas supply pipe 321 and the inert gas supply pipe 331 in communication with the gas supply spaces 222e may be connected to the lid member 222d that forms the gas supply space 222e in arbitrary directions, and thus, a degree of freedom of a pipe configuration can be sufficiently secured. In addition, when the magnetic fluid seal 222f is disposed between the lid member 222d and the outer circumferential surface of the column of the gas introduction shaft 22 that form the gas supply space 222e, since the gas introduction shaft 22 can be rotated in a state in which the lid member 222d is fixed, by rotating the cartridge head 20 rather than the substrate support unit 10, it is possible to realize the relative position movement of the cartridge head 20 and the substrate support unit 10. That is, even when the cartridge head 20 is rotated and the lid member 222d hermetically seals the annular gas supply space 222e via the magnetic fluid seal 222f, various gases can be supplied into each of the gas supply regions 213 through 215 of the gas supply plate 21.

(j) In addition, according to the embodiment, either the substrate support unit 10 or the cartridge head 20 is rotated for the relative position movement of the cartridge head 20 and the substrate support unit 10. For this reason, in comparison with the case in which the cartridge head 20 and the substrate support unit 10 are linearly moved for the relative position movement of the cartridge head 20 and the substrate support unit 10, since a simple and compact configuration of the mechanism or the like for relative position movement can be easily realized and the plurality of wafers W can be simultaneously processed, productivity of the film-forming processing can be improved. In addition, the gas supply regions 213 through 215 of the gas supply plate 21 can be arranged on the circumference, and thus, a high pressure gas can be efficiently supplied onto the wafer W on the substrate support unit 10.

### Another Embodiment

Hereinabove, the embodiment of the present invention has been described in detail, the present invention is not limited to the above-described embodiment but various modifications may be made without departing from the spirit of the present invention.

### (Number of Gas Supply Regions)

In the above-described embodiment, while the case in which the two or more source gas supply regions 213 and the two or more the reactive gas supply regions 214, and the inert gas supply regions 215 disposed between the source gas supply regions 213 and the reactive gas supply regions 214 are provided as the plurality of gas supply regions 213 through 215 of the gas supply plate 21 has been exemplarily described, the present invention is not limited thereto. That is, the present invention may be applied to the substrate processing apparatus as long as the processing space is divided into a plurality of gas supply regions.

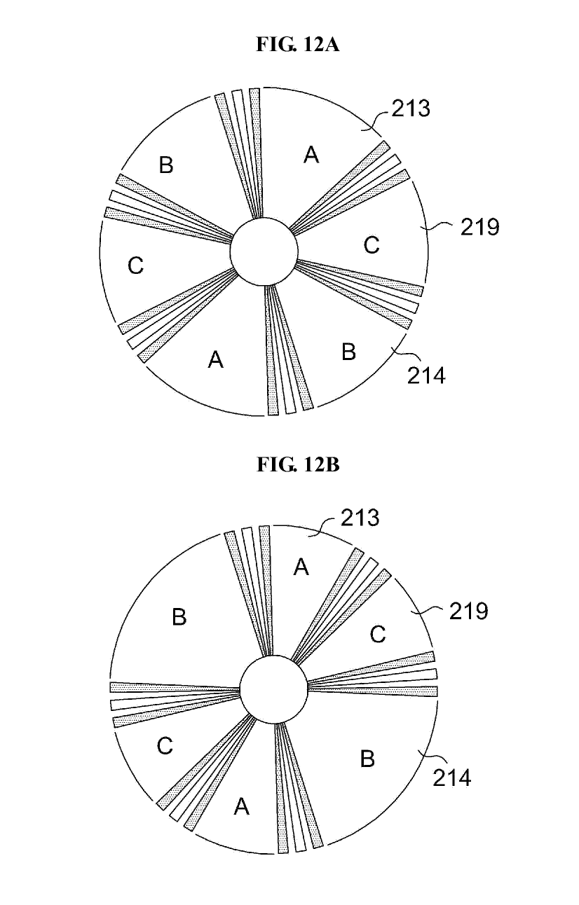

FIGS. 12A and 12B are views for describing an example of partitioned type gas supply regions of a substrate processing apparatus according to another embodiment of the present invention. In the drawings, the case including a first source gas supply region 213 serving as a source gas supply region configured to supply a first source gas onto the wafer W and a second source gas supply region 219 configured to supply a second source gas different from the first source gas onto the wafer W is shown. Similar to the case of the above-described embodiment, for example, TiCl₄ gas is used as the first source gas. In addition, for example, trimethyl aluminum (TMA) gas is used as the second source gas. In addition, the reactive gas (NH₃ gas) and the inert gas (N₂ gas) are similar to that of the above-described embodiment. When such a type of gas is supplied, a thin film of titanium aluminum nitride (TiAlN), which is a three-element alloy, can be formed on the wafer W.

In the example shown in FIG. 12A, positions of the exhaust regions 216 that separate the gas supply regions 213, 214, and 219 are set such that the first source gas supply region 213 (reference character A of the drawings), the reactive gas supply region 214 (reference character B of the drawings) and the second source gas supply region 219 (reference character C of the drawings) have the same area. In the above-described gas supply plate 21, the times during which the wafer W passes through the first source gas supply region 213, the second source gas supply region 219 and the reactive gas supply region 214, i.e., the times during which the wafer W is exposed to the first source gas, the second source gas and the reactive gas become substantially equal. On the other hand, in the example shown in FIG. 12B, positions of the exhaust regions 216 that separate the gas supply regions 213, 214 and 219 are set such that an area of the reactive gas supply region 214 (reference character B of the drawings) is larger than areas of the first source gas supply region 213 (reference character A of the drawings) and the second source gas supply region 219 (reference character C of the drawings). In the gas supply plate 21 having the above-described configuration, reaction amounts of the gases can be increased by supplying a larger amount of reactive gas than the first source gas and the second source gas onto the wafer W.

That is, for example, even when the thin film formed of the three-element alloy is formed on the wafer W, the plurality of gas supply plates 21 having the gas supply regions 213, 214 and 219 set to different sizes are prepared, one gas supply plate 21 appropriate for the type of thin film to be formed is selected, the selected gas supply plate 21 is mounted on the gas introduction shaft 22, and thus, the times during which the wafer W is exposed to the processing gases can be optimized.

In addition, while the reactive gas supply region is not shown in a partitioned form, in addition to the source gas supply region, a first reactive gas supply region and a second reactive gas supply region may be provided. Specifically, for example, HCDS (Si₂Cl₆) gas is used as the source gas, for example, NH₃ gas is used as the first reactive gas, and for example, oxygen gas (O₂ gas) is used as the second reactive gas. When such a type of gas is supplied, a thin film formed of SiON can be formed on the wafer W.

In addition, a region onto which a carbon source gas is supplied may be added to form a multi-element thin film such as a SiOCN film.

### (Plasma State of Reactive Gas)

In addition, in the above-described embodiment, while the example in which the reactive gas (NH₃ gas) is excited to a plasma state using the RPU 325 to be supplied into the reactive gas supply region 214 has been exemplified, the reactive gas may be excited to a plasma state using another technology.

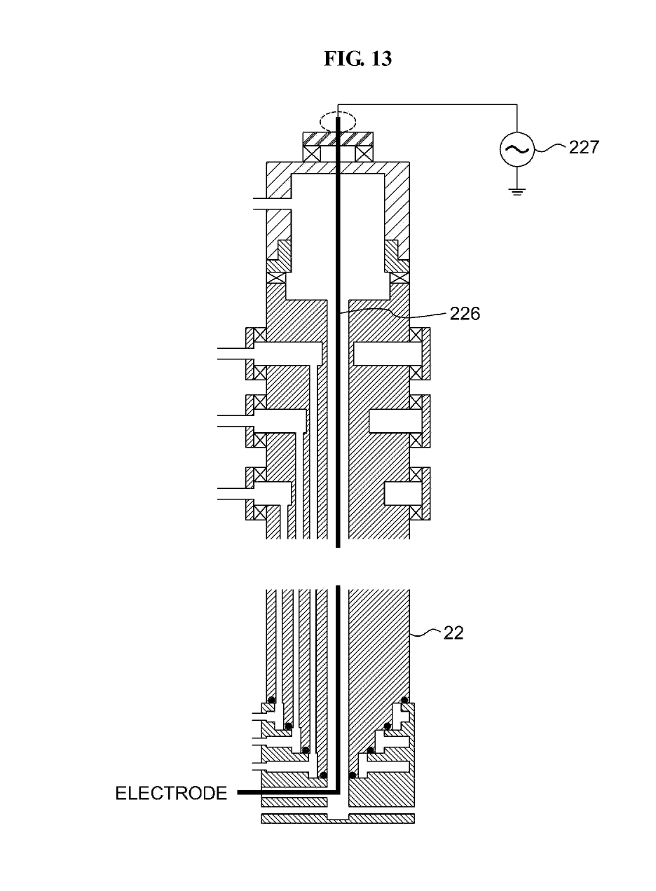

FIG. 13 is a view for describing a configuration example in which a reactive gas is excited to a plasma state in a substrate processing apparatus according to another embodiment of the present invention. In the configuration of FIG. 13, two electrodes (not shown) are installed to correspond to the gas supply plate 21 and the substrate support unit 10, respectively. One electrode is installed at the gas supply plate 21 side, and the other electrode is installed at the substrate support unit 10 side. The electrodes are disposed to oppose a surface to be processed at a height position of, for example, 5 mm to 25 mm from the surface to be processed of the wafer W on the substrate support unit 10. When the electrodes are installed in the vicinity of the extremes of the surface to be processed of the wafer W, the activated processing gas can be suppressed from being deactivated before reaching the wafer W. In addition, while a planar shape of each of the electrodes is formed in, for example, a comb shape, the embodiment is not limited thereto and it may be formed in one plate shape or a coil shape.

The electrode installed at the substrate support unit 10 side among the electrodes is connected to the earth (the ground). Meanwhile, a feed line 226 is connected to the electrode installed at the gas supply plate 21 side. The feed line 226 configured to supply power to the electrode of the gas supply plate 21 side is installed at the shaft center of the gas introduction shaft 22. In addition, the feed line 226 is connected to a high frequency power source 227 via an adapter (not shown). In addition, when the gas introduction shaft 22 is configured to be rotatable, the feed line 226 is configured to be connected to the high frequency power source 227 via a conductive brush or the like to be rotated with the gas introduction shaft 22.

When power is applied between the electrodes of the above-described configuration, the reactive gas is excited to a plasma state by electrical discharge. That is, even when the RPU 325 is not used, plasma can be generated in the reactive gas supply region 214 serving as a space into which the reactive gas is supplied. In addition, according to the above-described configuration, since the feed line 226 is disposed at the shaft center of the gas introduction shaft 22 to provide the plasma state in the reactive gas supply region 214, in comparison with a case in which it is disposed at a position other than the shaft center, a power supply mechanism to the feed line 226 can be simplified. In addition, it is possible to easily deal with the simplification even when the gas introduction shaft 22 is rotated, and inertia, when the gas introduction shaft 22 is rotated, can be reduced by positioning the feed line 226 at the shaft center (i.e., a rotational center).

### (Type of Gas)

In addition, for example, in the above-described embodiment, while the case in which the TiCl₄ gas is used as the source gas (the first processing gas) in the film-forming process performed by the substrate processing apparatus, the NH₃ gas is used as the reactive gas (the second processing gas), and these gases are alternately supplied to form the TiN film on the wafer W has been exemplarily described, the present invention is not limited thereto. That is, the processing gas used in the film-forming processing is not limited to the TiCl₄ gas or NH₃ gas but different types of thin films may be formed using different types of gases. In addition, even when three types of processing gases or more are used, the present invention may be applied as long as these gases are alternately supplied to perform the film-forming processing. In addition, the reactive gas is not limited to the case of being supplied in the plasma state but may be supplied after activation by heat.

### Other Embodiments

In addition, for example, in the above-described embodiments, while the film-forming processing is exemplified as the processing performed by the substrate processing apparatus, the present invention is not limited thereto. That is, in addition to the film-forming processing, the processing may be processing of forming an oxide film or a nitride film, or processing of forming a film including a metal as long as the substrate passes through a plurality of processing regions in sequence. In addition, regardless of specific contents of the substrate processing, the present invention may be applied to another substrate processing such as annealing processing, oxidation processing, nitration processing, diffusion processing, lithography processing, or the like, as well as the film-forming processing. In addition, the present invention may be applied to another substrate processing apparatus such as an annealing processing apparatus, an oxidation processing apparatus, a nitration processing apparatus, an exposure apparatus, an application apparatus, a drying apparatus, a heating apparatus, a processing apparatus using plasma and so on. In addition, these apparatuses may be combined in the present invention. In addition, a part of the configuration of the embodiment may be substituted with a configuration of another embodiment, or a configuration of another embodiment may be added to a configuration of a certain embodiment. In addition, other configurations may be added to, deleted from, or substituted with a part of the configuration of each of the embodiments.

According to the present invention, when the process processing in which the substrate passes through the plurality of processing regions in sequence is performed, a variation in sizes of the processing regions can be easily or conveniently provided according to the process processing.

### Preferred Embodiments

Hereinafter, preferred embodiments according to the present invention are supplementarily noted.

### Supplementary Note 1

According to an aspect of the present invention, there is provided a substrate processing apparatus including: a substrate support unit where a substrate is placed; a gas supply plate including: a processing space ceiling plate facing the substrate support unit; and a plurality of gas distribution pipes connected to a plurality of gas supply regions disposed between the processing space ceiling plate and the substrate support unit; and a gas introduction shaft mounted on the gas supply plate, the gas introduction shaft including a plurality of gas introduction pipes where different types of gases flow, wherein each of the plurality of gas introduction pipes is connected to each of the plurality of gas distribution pipes via each of a plurality of gas discharging spaces having annular shape.

### Supplementary Note 2

In the substrate processing apparatus of Supplementary note 1, preferably, the plurality of gas discharging spaces have different diameters and are disposed on different planes.

### Supplementary Note 3

In the substrate processing apparatus of any one of Supplementary notes 1 through 2, preferably, further includes a sealing member disposed at an engaging surface of the gas supply plate and the gas introduction shaft and configured to hermetically seal the plurality of gas discharging spaces.

### Supplementary Note 4

In the substrate processing apparatus of any one of Supplementary notes 1 through 3, preferably, the plurality of gas supply regions include: at least two source gas supply regions configured to supply a source gas to the substrate; and at least two reactive gas supply regions configured to supply a reactive gas to the substrate.

### Supplementary Note 5

In the substrate processing apparatus of Supplementary note 4, preferably, the surface area of the at least two source gas supply regions is different from that of the at least two reactive gas supply regions.

### Supplementary Note 6

In the substrate processing apparatus of Supplementary note 5, preferably, the surface area of the at least two source gas supply regions is smaller than that of the at least two reactive gas supply regions.

### Supplementary Note 7

In the substrate processing apparatus of any one of Supplementary notes 4 through 6, preferably, the at least two source gas supply regions include: a first source gas supply region configured to supply a first source gas to the substrate; and a second source gas supply region configured to supply a second source gas different from the first source gas to the substrate.

### Supplementary Note 8

In the substrate processing apparatus of any one of Supplementary notes 4 through 6, preferably, the at least two reactive gas supply regions include: a first reactive gas supply region configured to supply a first reactive gas to the substrate; and a second reactive gas supply region configured to supply a second reactive gas different from the first reactive gas to the substrate.

### Supplementary Note 9

In the substrate processing apparatus of any one of Supplementary notes 4 through 8, preferably, the plurality of gas supply regions further includes an inert gas supply region configured to supply an inert gas to the substrate.

### Supplementary Note 10

In the substrate processing apparatus of Supplementary note 9, preferably, the inert gas supply region is disposed between one of the at least two source gas supply region and one of the at least two reactive gas supply region.

### Supplementary Note 11

In the substrate processing apparatus of any one of Supplementary notes 1 through 10, preferably, the gas introduction shaft further includes a gas exhaust pipe disposed at a center thereof.

### Supplementary Note 12

In the substrate processing apparatus of any one of Supplementary notes 1 through 11, preferably, further includes a moving mechanism configured to move a relative position between the substrate and the gas supply plate coupled to the gas introduction shaft in a manner that the substrate pass through the plurality of gas supply regions in sequence.

### Supplementary Note 13

In the substrate processing apparatus of Supplementary note 12, preferably, the gas introduction shaft includes a gas supply space having annular shape and configured to introduce a gas to the gas introduction shaft.

### Supplementary Note 14

In the substrate processing apparatus of any one of Supplementary notes 1 through 13, preferably, further includes: an electrode disposed at the gas supply plate; and a feed wire disposed at a center of the gas introduction shaft and configured to supply power to the electrode.

### Supplementary Note 15

According to another aspect of the present invention, there is provided a gas introduction shaft used for introducing a gas into a processing space above a substrate support unit where a substrate is placed, the gas introduction shaft including: a plurality of gas introduction pipes where different types of gases flow, wherein the gas introduction shaft is mounted on a gas supply plate including: a processing space ceiling plate facing the substrate support unit; and a plurality of gas distribution pipes connected to a plurality of gas supply regions disposed between the processing space ceiling plate and the substrate support unit, and wherein each of the plurality of gas introduction pipes is connected to each of the plurality of gas distribution pipes via each of a plurality of gas discharging spaces having annular shape.

### Supplementary Note 16

In the gas introduction shaft of Supplementary note 15, preferably, the plurality of gas discharging spaces have different diameters and are disposed on different planes.

### Supplementary Note 17

In the gas introduction shaft of any one of Supplementary notes 15 through 16, preferably, further includes a sealing member disposed at an engaging surface of the gas supply plate and the gas introduction shaft and configured to hermetically seal the plurality of gas discharging spaces.

### Supplementary Note 18

According to still another aspect of the present invention, there is provided a gas supply plate used for introducing a gas into a processing space above a substrate support unit where a substrate is placed, the gas supply plate including: a processing space ceiling plate facing the substrate support unit; and a plurality of gas distribution pipes connected to a plurality of gas supply regions disposed between the processing space ceiling plate and the substrate support unit, wherein the gas supply plate is coupled to a gas introduction shaft including a plurality of gas introduction pipes where different types of gases flow, and wherein each of the plurality of gas distribution pipes is connected to each of the plurality of gas introduction pipes via each of a plurality of gas discharging spaces having annular shape.

### Supplementary Note 19

In the gas supply plate of Supplementary note 18, preferably, the plurality of gas discharging spaces have different diameters and are disposed on different planes.

### Supplementary Note 20

In the gas supply plate of any one of Supplementary notes 18 through 19, preferably, further includes a sealing member disposed at an engaging surface of the gas supply plate and the gas introduction shaft and configured to hermetically seal the plurality of gas discharging spaces.

### Supplementary Note 21

According to still another aspect of the present invention, there is provided a method of manufacturing a semiconductor device including: (a) placing a substrate on a substrate support unit; (b) mounting a gas introduction shaft including a plurality of gas introduction pipes where different types of gases flow on a gas supply plate including a processing space ceiling plate facing the substrate support unit and a plurality of gas distribution pipes connected to a plurality of gas supply regions disposed between the processing space ceiling plate and the substrate support unit in a manner that each of the plurality of gas introduction pipes is connected to each of the plurality of gas distribution pipes via each of a plurality of gas discharging spaces having annular shape; (c) supplying a gas into each of the plurality of gas supply regions through the gas introduction shaft, the plurality of gas discharging spaces and the plurality of gas distribution pipes; and (d) moving a relative position between the substrate and the gas supply plate coupled to the gas introduction shaft.

What is claimed is:

1. A substrate processing apparatus comprising:
a substrate support unit where a substrate is placed;
a gas supply plate comprising: a processing space ceiling plate facing the substrate support unit; and a plurality of gas distribution pipes connected to a plurality of gas supply regions disposed between the processing space ceiling plate and the substrate support unit; and
a gas introduction shaft mounted on the gas supply plate, the gas introduction shaft comprising a plurality of gas introduction pipes where different types of gases flow, wherein each of the plurality of gas introduction pipes is connected to each of the plurality of gas distribution pipes via each of a plurality of gas discharging spaces having annular shape, and the plurality of gas discharging spaces have different diameters and are disposed on different planes.

2. The substrate processing apparatus of claim 1, wherein the gas introduction shaft comprises a protruding portion having steps, and the gas supply plate comprises a groove portion having steps, and wherein the gas introduction shaft is coupled to the gas supply plate in a manner that a horizontal surface of the steps of the groove portion and a horizontal surface of the steps of the protruding portion are on a same plane.

3. The substrate processing apparatus of claim 1, further comprising a sealing member disposed at an engaging surface of the gas supply plate and the gas introduction shaft and configured to hermetically seal the plurality of gas discharging spaces.

4. The substrate processing apparatus of claim 1, wherein the gas introduction shaft comprises a protruding portion having steps, and the plurality of gas discharging spaces are arranged along a horizontal surface of the steps of the protruding portion.

5. The substrate processing apparatus of claim 1, wherein the gas supply plate comprises a groove portion having steps, and the plurality of gas discharging spaces are arranged to be in contact with horizontal and vertical surfaces of the steps of the groove portion.

6. The substrate processing apparatus of claim 1, further comprising:
a gas exhaust pipe disposed at a center of the gas introduction shaft; and
a feed wire installed in the gas exhaust pipe and configured to supply high frequency power to the gas supply plate.

7. A gas introduction shaft used for introducing a gas into a processing space above a substrate support unit where a substrate is placed, the gas introduction shaft comprising:
a plurality of gas introduction pipes where different types of gases flow, wherein the gas introduction shaft is mounted on a gas supply plate comprising:
a processing space ceiling plate facing the substrate support unit; and
a plurality of gas distribution pipes connected to a plurality of gas supply regions disposed between the processing space ceiling plate and the substrate support unit, and wherein each of the plurality of gas introduction pipes is connected to each of the plurality of gas distribution pipes via each of a plurality of gas discharging spaces having annular shape, and the plurality of gas discharging spaces have different diameters and are disposed on different planes.

8. The gas introduction shaft of claim 7, further comprising a protruding portion having steps, wherein the gas introduction shaft is coupled to the gas supply plate in a manner that a horizontal surface of steps of a groove portion of the gas supply plate and a horizontal surface of the steps of the protruding portion are on a same plane.

9. The gas introduction shaft of claim 7, further comprising a sealing member disposed at an engaging surface of the gas supply plate and the gas introduction shaft and configured to hermetically seal the plurality of gas discharging spaces.

10. The gas introduction shaft of claim 7, further comprising a protruding portion having steps, and wherein the plurality of gas discharging spaces are arranged along a horizontal surface of the steps of the protruding portion.

11. The gas introduction shaft of claim 7, further comprising:
a gas exhaust pipe disposed at a center thereof; and
a feed wire installed in the gas exhaust pipe and configured to supply high frequency power to the gas supply plate.

12. A gas supply plate used for introducing a gas into a processing space above a substrate support unit where a substrate is placed, the gas supply plate comprising:
a processing space ceiling plate facing the substrate support unit; and
a plurality of gas distribution pipes connected to a plurality of gas supply regions disposed between the processing space ceiling plate and the substrate support unit, wherein the gas supply plate is coupled to a gas introduction shaft comprising a plurality of gas introduction pipes where different types of gases flow, and wherein each of the plurality of gas distribution pipes is connected to each of the plurality of gas introduction pipes via each of a plurality of gas discharging spaces having annular shape, and the plurality of gas discharging spaces have different diameters and are disposed on different planes.

13. The gas supply plate of claim 12, further comprising a groove portion having steps, and wherein the gas supply plate is coupled to the gas introduction shaft in a manner that a horizontal surface of the steps of the groove portion and a horizontal surface of steps of a protruding portion of the gas introduction shaft are on a same plane.

14. The gas supply plate of claim 12, further comprising a sealing member disposed at an engaging surface of the gas supply plate and the gas introduction shaft and configured to hermetically seal the plurality of gas discharging spaces.

15. The gas supply plate of claim 12, wherein the gas supply plate comprises a groove portion having steps, and the plurality of gas discharging spaces are arranged to be in contact with horizontal and vertical surfaces of the steps of the groove portion.
